(19) United States
(12) Patent Application Publication
(10) Pub. No.: US 2025/0015558 A1
(43) Pub. Date: Jan. 9, 2025

(54) HIGH POWER GALLIUM AND NITROGEN CONTAINING LASER DIODE DEVICES WITH A MODULATION DEVICE

(71) Applicant: KYOCERA SLD Laser, Inc., Goleta, CA (US)

(72) Inventors: Philip Chan, Goleta, CA (US); Phillip Skahan, Goleta, CA (US); James W. Raring, Santa Barbara, CA (US); Nicholas J. Pfister, Goleta, CA (US)

(73) Assignee: KYOCERA SLD Laser, Inc., Goleta, CA (US)

(21) Appl. No.: 18/892,174

(22) Filed: Sep. 20, 2024

Related U.S. Application Data
(63) Continuation-in-part of application No. 18/228,633, filed on Jul. 31, 2023.
(60) Provisional application No. 63/465,353, filed on May 10, 2023.

(51) Int. Cl. H01S 5/042; H01S 5/02355; H01S 5/026; H01S 5/06; H01S 5/12; H01S 5/343

(52) U.S. Cl. CPC H01S 5/0421; H01S 5/02355; H01S 5/0265; H01S 5/0612; H01S 5/12; H01S 5/34333

(57) ABSTRACT

According to the present invention, techniques for high power gallium and nitrogen containing laser diode devices are provided. Such high-power devices include straight lasers, tapered lasers, distributed feedback lasers, distributed Bragg reflector laser devices, and power amplifier devices configured with improved mode quality, each of which can be modulated using a modulator device.

### CROSS-REFERENCE TO RELATED APPLICATIONS

This application is a Continuation-In-Part of U.S. patent application Ser. No. 18/228,633, filed Jul. 31, 2023, which claims priority to U.S. Provisional Application No. 63/465,353, filed May 10, 2023, each of which is commonly owned and the entire contents of which are incorporated herein by reference for all purposes.

### BACKGROUND

Devices based on wide bandgap III-V semiconductor materials such as gallium nitride (GaN) play a major role in our modern world. They play critical roles in essentially all electronic devices and are instrumental in almost all of the machines and apparatus we rely on every day. Examples of such semiconductor devices include light emitting devices such as light emitting diodes and laser diodes. Forming such GaN devices of the highest performance often requires epitaxial structures with minimum defect density and the highest crystal quality and purity. To achieve the low defect density and high crystal quality it is most optimum to grow the device epitaxial layers on a native GaN substrates to form a pseudomorphic epitaxial structure that is relatively free from strain related defects that occur when growing on foreign substrates.

Unfortunately, the synthesis of GaN single crystal substrates has been an extraordinarily difficult task. The highly successful Czochralski method for silicon crystal growth would have impractical process requirements comparable to conditions very deep within the Earth's mantle. Alternative approaches have been investigated for growing GaN bulk substrates, such as hydride vapor phase epitaxy (HVPE) and ammonothermal growth. Additionally, it is still a great challenge to scale up bulk GaN growth to larger wafer sizes. GaN substrates are currently available in 2″ diameter at high volume, and recent announcements have revealed availability in 4″ in the near future, which is still drastically smaller than more mature substrate technologies such as 12″ single crystal silicon. At the current GaN wafer diameter and prices, the native substrate option is not economically feasible for realizing semiconductor devices in many applications, specifically light emitting diode applications and power electronic applications. Given the obstacles in GaN native substrate manufacturing, there has been substantial effort devoted to the epitaxy on foreign substrate materials. Common choices for GaN heteroepitaxy include sapphire, silicon carbide, and silicon. In the past decade, SiC and sapphire substrates have been widely used in nitride LEDs and RF transistors.

A laser diode is a two-lead semiconductor light source that emits electromagnetic radiation that is comprised primarily of stimulated emission. The laser diode is comprised of a gain medium that functions to provide emission through the recombination of electron-hole pairs and a cavity region that functions as a resonator for the emission of the gain medium. When a suitable voltage is applied to the leads to sufficiently pump the gain medium, the cavity losses are overcome by the gain and the laser diode reaches the so-called threshold condition, wherein a steep increase in the light output versus current input characteristic is observed. Unlike LEDs, laser diodes emit very directional light and have orders of magnitude higher spatial brightness. Moreover, above threshold, they do not suffer from the droop phenomenon that plagues LEDs.

Early visible laser technology comprised lamp pumped infrared solid-state lasers with the output wavelength converted to the visible using specialty crystals with nonlinear optical properties. For example, a green lamp pumped solid state laser had 3 stages: electricity powers lamp, lamp excites gain crystal which lases at 1064 nm, 1064 nm goes into frequency conversion crystal which converts to visible 532 nm. The resulting green and blue lasers were called “lamped pumped solid-state lasers with second harmonic generation” (LPSS with SHG) and had wall plug efficiency of ˜1% and were more efficient than Ar-ion gas lasers, but were still too inefficient, large, expensive, and fragile for broad deployment outside of specialty scientific and medical applications. To improve the efficiency of these visible lasers, high power diode (or semiconductor) lasers were utilized. These “diode pumped solid state lasers with SHG” (DPSS with SHG) had 3 stages: electricity powers 808 nm diode laser, 808 nm excites gain crystal, which lases at 1064 nm, 1064 nm goes into frequency conversion crystal which converts to visible 532 nm. As high-power laser diodes evolved and new specialty SHG crystals were developed, it became possible to directly convert the output of the infrared diode laser to produce blue and green laser light output. These “directly doubled diode lasers” or SHG diode lasers had 2 stages: electricity powers 1064 nm semiconductor laser, 1064 nm goes into frequency conversion crystal which converts to visible 532 nm green light. These lasers designs are meant to improve the efficiency, cost and size compared to DPSS-SHG lasers, but the specialty diodes and crystals required make this challenging today.

Based on essentially all the pioneering work on GaN LEDs, visible laser diodes based on GaN technology have emerged. Currently the only viable direct blue and green laser diode structures are fabricated from the wurtzite AlGaInN material system. The manufacturing of light emitting diodes from GaN related materials is dominated by the heteroepitaxial growth of GaN on foreign substrates such as Si, SiC and sapphire. Laser diode devices operate at such high current densities that the crystalline defects associated with heteroepitaxial growth are not acceptable. Because of this, very low defect-density, free-standing GaN substrates have become the substrate of choice for GaN laser diode manufacturing. Unfortunately, such bulk GaN substrates are costly and not widely available in large diameters. For example, 2″ diameter is the most common bulk GaN c-plane substrate size today with recent progress enabling 4″ diameter, which are still relatively small compared to the 6″ and greater diameters that are commercially available for mature substrate technologies.

Lasers rely on feedback of light into an optical cavity. In a Fabry-Perot laser, this feedback is from facets and dielectric facet coatings which are broadband reflectors. Because the facets and coatings reflect over a broad wavelength range, many longitudinal modes are supported in the cavity. This leads to wide spectral widths in the hundreds or thousands of picometers. Some applications, for example sensing, communication or coupling into an external waveguide, benefit from narrow spectral widths or even a single longitudinal lasing mode. To achieve a single longitudinal mode or single frequency operation, narrow-band mirrors in the form of gratings provide wavelength-dependent feedback to the cavity and act as a mode filter.

### SUMMARY

Examples of the invention provide semiconductor laser devices and methods of manufacturing the devices. Typically, these devices are fabricated using an epitaxial deposition and processing followed by transfer to a carrier substrate. What follows is a general description of exemplary configurations and fabrication methods of these devices.

In an example, the present invention provides a high mode quality GaN laser configured with a modulator device.

In an example, the present invention provides an electro absorption modulator (EAM) device configured within a portion of the cavity region. In an example, the device is adapted to modulate the laser beam. Preferably, the EAM device comprises a pair of electrodes, the biasing of which causes the laser beam to traverse, stop, or be modulated within the cavity region.

In an example, the present invention provides a laser device containing a gallium and nitrogen containing material. The device includes a carrier substate member comprising a front side and a back side; a bonding material overlying the front side of the carrier substrate member and configured to bond an overlying transferred material to the front side of the carrier substrate member; at least one p-type contact region overlying the bonding material and configured to form a thermal path and an electrical path to and from the bonding material; a p-type gallium and nitrogen containing region overlying the at least one p-type contact region; an active region overlying the p-type gallium and nitrogen containing region, the active region comprising a plurality of quantum well regions; an n-type gallium and nitrogen containing region overlying the active region, the n-type gallium and nitrogen containing region comprising a plurality of sub-regions; at least one n-type contact region overlying the n-type gallium and nitrogen containing region; and a waveguide region including a laser diode portion configured to propagate electromagnetic radiation and output a laser beam; and an electro absorption modulator (EAM) portion configured to modulate the laser beam, the EAM portion associated with a pair of electrodes configured to cause the laser beam to traverse, stop, or be modulated within the EAM portion.

In an example, at least a portion of the at least one n-type contact region comprises a spatial pattern having a dimension and geometry to achieve a predetermined mode quality.

In another example, the laser diode portion of the waveguide region is associated with an etched grating disposed in the n-type gallium and nitrogen containing region.

In another example, the laser diode portion and the EAM portion are separated by a current isolation region.

In another example, the at least one p-type contact region includes an anode associated with the laser diode region and a separate anode associated with the EAM region.

In yet another example, the pair of electrodes associated with the EAM portion include an n-type contact region and a p-type contact region.

In another example, the present invention provides a laser device containing a gallium and nitrogen containing material. The device includes a carrier substate member comprising a front side and a back side; a bonding material overlying the front side of the carrier substrate member and configured to bond an overlying transferred material to the front side of the carrier substrate member; a p-type contact region overlying the bonding material and configured to form a thermal path and an electrical path to and from the bonding material; a p-type gallium and nitrogen containing region overlying the p-type contact region; an active region overlying the p-type gallium and nitrogen containing region, the active region comprising a plurality of quantum well regions; an n-type gallium and nitrogen containing region overlying the active region, the n-type gallium and nitrogen containing region comprising a plurality of sub-regions; an n-type contact region overlying the n-type gallium and nitrogen containing region; a cavity region formed between a first facet and a second facet and configured to propagate electromagnetic radiation through the cavity region and output a laser beam from one of the first facet or the second facet; and an electro absorption modulator (EAM) device arranged to receiver the laser beam from the cavity region and adapted to modulate the laser beam, the electro absorption modulator device comprising a pair of electrodes configured to cause the laser beam to traverse, stop, or be modulated within the cavity region.

In an example, the n-type contact region comprises a spatial pattern having a dimension and a geometry to achieve a predetermined mode quality.

In another example, the cavity region is separated from the EAM device by a gap.

In yet another example, the cavity region includes an etched grating overlying the n-type gallium and nitrogen containing region.

In another example, the present invention provides a laser device containing a gallium and nitrogen containing material. The device includes a carrier substate member comprising a front side and a back side; a bonding material overlying the front side of the carrier substrate member and configured to bond an overlying transferred material to the front side of the carrier substrate member; at least one p-type contact region overlying the bonding material and configured to form a thermal path and an electrical path to and from the bonding material; a p-type gallium and nitrogen containing region overlying the at least one p-type contact region; an active region overlying the p-type gallium and nitrogen containing region, the active region comprising a plurality of quantum well regions; an n-type gallium and nitrogen containing region overlying the active region, the n-type gallium and nitrogen containing region comprising a plurality of sub-regions; at least one n-type contact region overlying the n-type gallium and nitrogen containing region; and a cavity region formed between a first facet and a second facet and configured to propagate electromagnetic radiation through the cavity region and output a laser beam from one of the first facet or the second facet, the cavity region including a laser diode portion, an electro absorption modulator (EAM) portion, and an amplifier portion. The EAM portion may be configured to modulate the laser beam, the EAM portion associated with a pair of electrodes configured to cause the laser beam to traverse, stop, or be modulated within the EAM portion, and the amplifier portion may be configured to expand lasing mode and reduce power density.

In an example, at least a portion of the at least one n-type contact region comprises a spatial pattern having a dimension and a geometry to achieve a predetermined mode quality.

In another example, the laser diode portion of the cavity region is associated with an etched grating disposed in the n-type gallium and nitrogen containing region.

In another example, the laser diode portion and the EAM portion are separated by a current isolation region, and the EAM portion and the amplifier portion are separated by a current isolation portion.

In another example, the EAM portion is disposed between the laser diode portion and the amplifier portion.

In another example, the cavity is tapered in at least the amplifier portion.

In another example, the cavity includes a curve or bend between the laser diode portion and the amplifier portion.

In another example, at least one of the first facet or the second facet is angled relative to a longitudinal axis of the cavity.

In another example, the device also includes a power monitoring photodiode configured to determine output power from the laser diode portion.

In another example, the device also includes a micro-heater configured to thermally tune a wavelength of the laser beam.

In another example, the device also includes a segmented cathode on the laser diode portion configured to laterally drive current to tune a wavelength of the laser beam.

In yet another example, the device also includes a means for modulating a drive current to tune a wavelength of the laser beam.

Various benefits and/or advantages are achieved using one or more aspects of the present invention. One or more advantages of the various embodiments may include:

Improved reliability: In an example, patterned n-region contacts reduce a risk of catastrophic optical damage (COD) in high-power lasers. As COD rate is proportional to the optical power density at the facet, reduction in local power density causes a simultaneous reduction in COD rate. Optical damage occurs when the laser output power causes thermal damage to the laser facet, which can lead to device failure. By reducing the areas of high optical power density caused from filamentation, patterned n-type region contacts reduce a risk of optical damage and improve the reliability of the laser.

Enhanced beam quality: In an example, reduced filamentation and superior mode control offered by patterned n-region contacts enabled by present transfer techniques can improve the beam quality of the laser, leading to a narrower and more stable output beam.

Optical Profile: Reduction of filamentation creates a manageable, uniform near-field intensity pattern for uniform spot size.

Modulated laser beam: Electro adsorption modulator device configured to modulate the laser beam.

The present invention achieves these benefits and others in the context of known process technologies. However, a further understanding of the nature and advantages of the present invention may be realized by reference to the latter portions of the specification and attached drawings.

### BRIEF DESCRIPTION OF THE DRAWINGS

FIG. 1 is a simplified diagram of a conventional laser device.

FIG. 2 is a simplified side view diagram of an edge emitting laser diode according to an example of the present invention.

FIG. 3 is a more detailed diagram illustrating an n-type region, including sub-regions, for a laser diode according to an example of the present invention.

FIG. 4 is an image of a ridge structure including patterned contact for a laser diode according to an example of the present invention.

FIG. 5 is a top-view diagram of various patterned contact regions according to an example of the present invention.

FIG. 6 is a top-view diagram of alternative patterned contact regions according to an example of the present invention.

FIG. 7 is a top-view diagram of alternative patterned contact regions according to an example of the present invention.

FIG. 8 is a simplified side-view diagram of a laser diode according to an example of the present invention.

FIG. 9 is a simplified side-view diagram of a laser diode according to an example of the present invention.

FIG. 10 is a simplified top-view diagram of a tapered waveguide laser device according to an example of the present invention.

FIG. 11 is a simplified top view diagram of a straight laser diode configured with a tapered waveguide laser diode according to an example of the present invention.

FIG. 12 is a simplified illustration of images of tapered waveguide laser diodes according to an example of the present invention.

FIG. 13 is a simplified illustration of mask devices for a tapered waveguide laser diode according to an example of the present invention.

FIG. 14 is a simplified illustration of various patterned contact regions of tapered waveguide laser diodes according to examples of the present invention.

FIG. 15 is a simplified illustration of a distributed feedback laser diode device according to an alternative example of the present invention.

FIG. 16 is a simplified illustration of a distributed feedback laser diode device according to an alternative example of the present invention.

FIG. 17 is a simplified side-view diagram of a MOPA device according to an example of the present invention.

FIG. 18 is a simplified top-view diagram of a MOPA device configured with a tapered amplifier according to an example of the present invention.

FIG. 19 is a simplified perspective-view diagram of a tapered waveguide laser diode device according to an example of the present invention.

FIG. 20 is a simplified top-view diagram of a MOPA device configured with a single frequency according to an example of the present invention.

FIG. 21 is a simplified top-view diagram of a MOPA device configured with a distributed feedback reflector and a distributed Bragg reflector according to an example of the present invention.

FIG. 22 is a simplified top-view diagram of a single frequency laser diode device configured with a distributed feedback reflector according to an example of the present invention.

FIG. 23 illustrates a MOPA or taped waveguide laser device configured with various patterned contact regions according to an example of the present invention.

FIGS. 24 to 29 illustrate various view of an array of lasers or MOPAs that are configured as laser bars according to examples of the present invention.

FIG. 30 illustrates schematic representation of four main methods of incoherent beam combining according to an example of the present invention.

FIG. 31 is a simplified general schematic illustration of coherent beam combining (CBC) according to an example of the present invention.

FIGS. 32-43 are simplified top-view and cross-sectional diagrams of MOPA devices according to examples of the present invention.

FIGS. 44-46 are simplified top-view and block diagrams of MOPA devices and example optics according to examples of the present invention.

FIGS. 47-54 are simplified diagrams of various laser devices configured with an electro-absorption modulator (EAM) device according to examples of the present invention.

### DETAILED DESCRIPTION

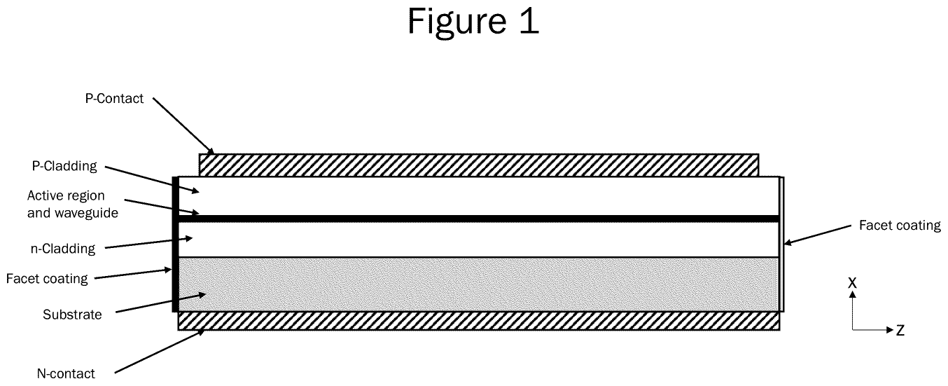

FIG. 1 is a simplified diagram of a conventional GaN laser diode device. As shown, the conventional device has a p-type region forming a p-type contact, which faces out, and an n-type region is formed underlying a substrate member. Although useful for certain applications, the conventional device has limitations. That is, the conventional device is not operable efficiently at higher order modes, does not produce high output power, and other performance limitations.

As the cavity width is increased a laser diode will support higher order spatial (lateral) modes beyond the fundamental mode that a single mode operates with. These higher order modes can degrade the laser beam quality as measured by the beam quality factor (m2). This limits the brightness of the laser or the degree to which the beam can be focused for a given beam divergence angle. The mode quality and brightness can be degraded for various reasons including higher slow axis divergences angles of the higher order mode, which in turn reduces brightness, increases filamentation, and increases thermal lensing.

In single lateral mode GaN laser devices with narrow waveguides (1 m-3 m), the mode quality and divergence are controlled through the lateral waveguide design, the epitaxial layer design, and with uniform electrical and material properties. However, uniform narrow waveguide single mode laser devices in GaN are limited to optical output powers of less than about 500 mW or less than about 1 W, making them undesirable for reliable, high-power applications where multiple watts, kilowatts, or even megawatts are needed.

To scale the power of the laser diodes, multi-mode lasers with wider stripe dimensions of >3 um, >10 um, >30 um, >60 um, or even >100 um are often deployed. In these multimode high-power devices, the mode quality and the brightness often suffer. To improve the mode quality there are several practices that can be implemented such as suppressing higher order modes, suppressing filamentation or thermal lensing, or modifying the waveguide design using approaches such as tapering which filters higher order lateral modes and can even enable single spatial mode operation.

For single frequency devices that operate both with single lateral and a single cavity (longitudinal) mode, the challenge is even in achieving high power while maintaining good mode quality. In high power single frequency devices designs must be implemented to maintain a single lateral mode such as with a waveguide taper and maintain a single cavity mode such as with distributed Bragg reflectors (DBR) or distributed feedback (DFB) structures. In one example, a master oscillator power amplifier (MOPA) using a DFB as the seed laser/master oscillator is used to form a high-power single frequency laser. Further details of the present invention and techniques to overcome one or more of the limitations are provided throughout the present specification and more particularly below.

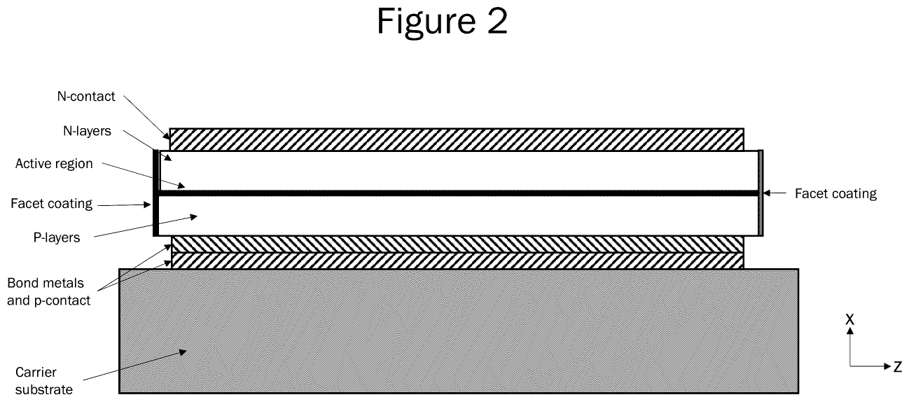

FIG. 2 is a simplified side view diagram of an edge emitting laser diode according to an example of the present invention. As shown, the N-contact is on top of the transferred epi layers and p-type region contact is on the bottom of the transferred epi layers. The p-type region contact metal is within a metal stack that includes the bond metals and is bonded to a metal layer that is contained within a metal stack on the carrier substrate to create a bond interface. In this configuration the n-type region contact and p-type region contact are deposited directly on epitaxial layers and are configured on the top and bottom of the laser cavity and are spatially aligned so that one is at least partially overlying the other. An example of a manufacturing process to fabricate the edge emitting laser diode is described in U.S. Pat. No. 9,666,677 and U.S. Publication No. 2022/0344476, which are commonly assigned and hereby incorporated by reference in their entirety.

In a preferred example, the present laser diode is configured with patterned contact regions for a p-type region contact. In an example, the present contact regions can be patterned with selected dimensions, shapes, and geometries in combination with n-type region epitaxial layers between the n-type contact region and the active region of the laser diodes. In an example, the layers preferably are comprised of GaN, AlGaN, InAlGaN, or any combination. Such layers are also introduced with impurities to dope intentionally with an n-type species such as silicon, and others. In an example, such layers include one or more regions with various doping levels ranging from about 1E17 cm-3 to about 5E19 cm-3, or concentrations in between. The separate layer thicknesses could range from about 1 nm to about 1 um, and the total thickness could range from about 100 nm to about 3 um. The thicknesses, composition, and doping levels in design with the metal or conductive oxide contacts would dictate the current injection pattern, and hence the mode quality.

In an example, the present laser diode configured with patterned n-region contacts improves optical mode quality. In an example, patterning the n-region contacts modulates the current injection pattern into the laser diode to control mode stability and prevent filamenting of the laser diode or amplifier region.

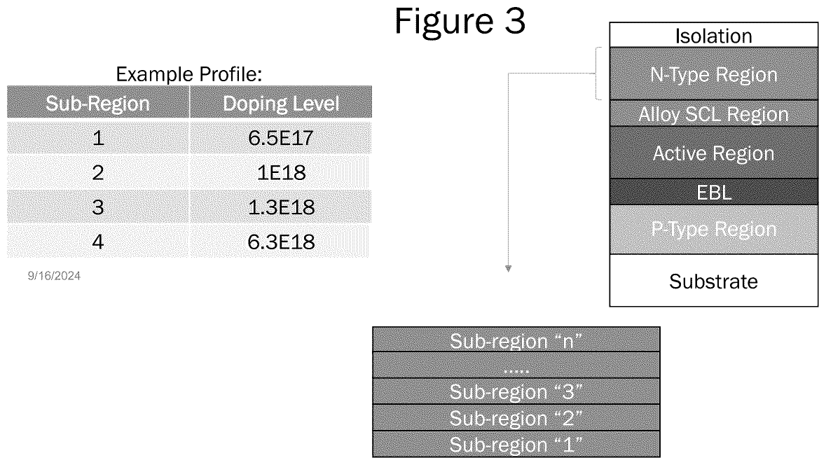

FIG. 3 is a more detailed diagram illustrating an n-type region, including sub-regions, for a laser diode according to an example of the present invention. As shown, the laser diode includes an upper n-type region and overlying isolation region. The n-type region can be continuous or have a plurality of sub regions. In an example, the n-type region is designed with different thicknesses and doping using silicon, for example, to achieve desirable current spreading for injection into an underlying active region. In an example, doping level of the n-type region may vary from 1E17 to 1E20 cm⁻³ of n-type species dopant, e.g., silicon. In an example, any n-type dopant entity can be used, although silicon species are desirable. In an example, the doping profile can vary. For example, the doping profile for the n-type region may or may not be uniform, or the doping profile for the n-type region may or may not be graded, or the n-type region may be broken into sub-regions of different doping level(s) to create a nonuniform profile or uniform doping profile. In an example, the type and number of sub regions and doping profiles may vary. That is, the doping profile may or may not be continuous and/or smooth, or the doping profile can have other variations.

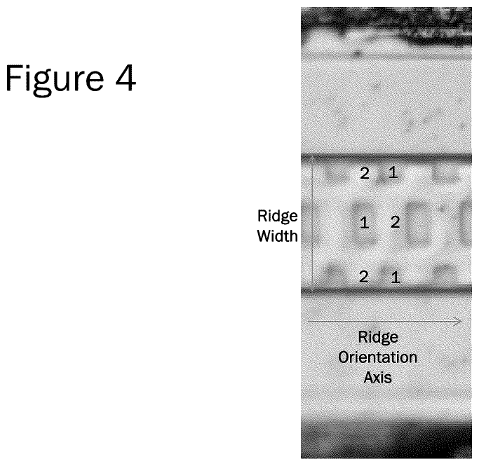

FIG. 4 is an image of a ridge structure including patterned contact for a laser diode according to an example of the present invention. In an example, the image illustrates dependence of index of refraction on modal gain/loss, carrier density, and temperature results in non-linear effects such as filamentation and spatial hole burning.

In an example, the image illustrates an indication that patterning of the contact electrodes on laser diodes provide modulation of current density in the active region. In an example, an open region in the pattern has no direct current injection at the contact regions. A contact material has direct current injection at contacts. In an example, a strength of modulation will depend on current spreading of n-side cladding layers and a contact fill factor. In an example, modulation of current in the active region will induce gain modulation and consequently variation of refractive index.

As shown, by alternating the patterns along a ridge structure along a direction of the axis, we achieve different order waveguide modes favored by the current/gain modulation at each point. Any filamentation or non-uniform variation of waveguide mode shape tends to be desirably suppressed.

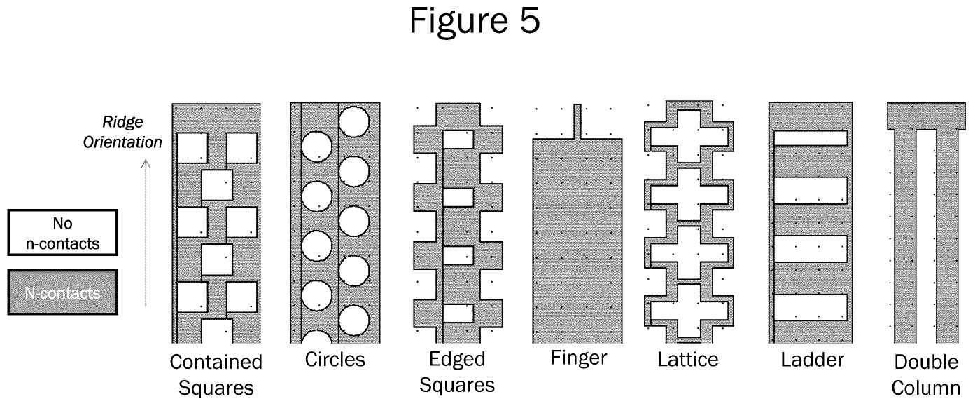

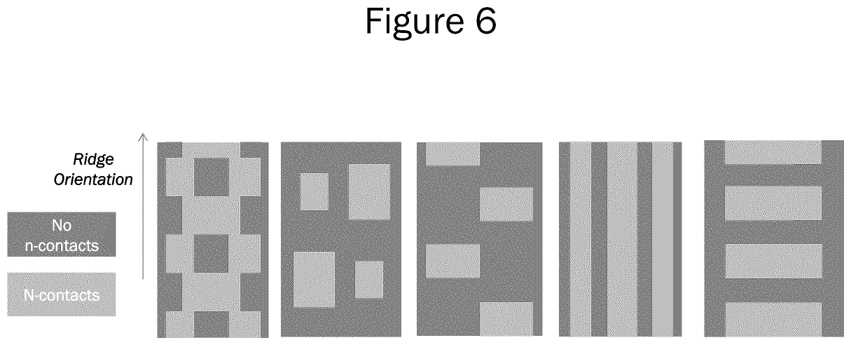

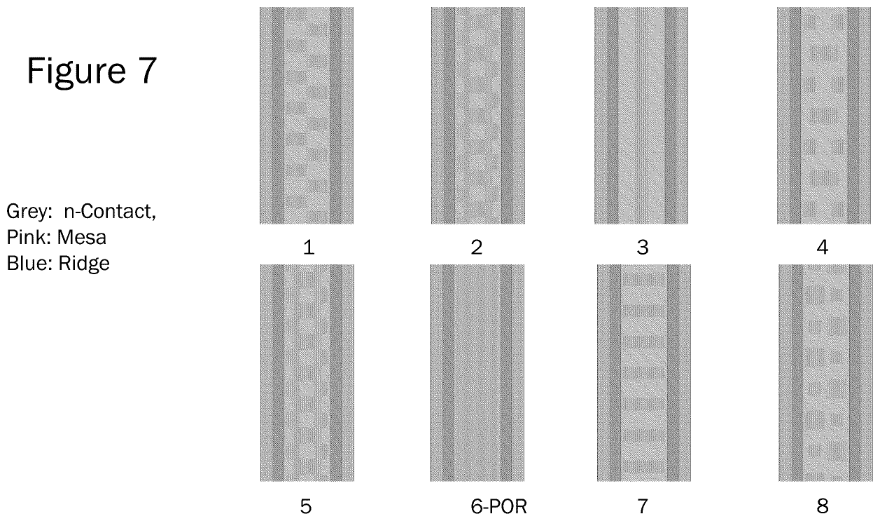

FIG. 5 is a top-view diagram of various patterned contact regions according to an example of the present invention. As shown, a plurality of different contact region patterns is included. For example, the pattern includes a replica of an n-chip pattern design, patterns with only longitudinal modulation, patterns with only lateral modulation, and other pattern variations in combination with epitaxial structures for desired and predetermined current injection patterns. FIG. 6 is a top-view diagram of alternative patterned contact regions according to an example of the present invention. FIG. 7 is a top-view diagram of alternative patterned contact regions according to an example of the present invention.

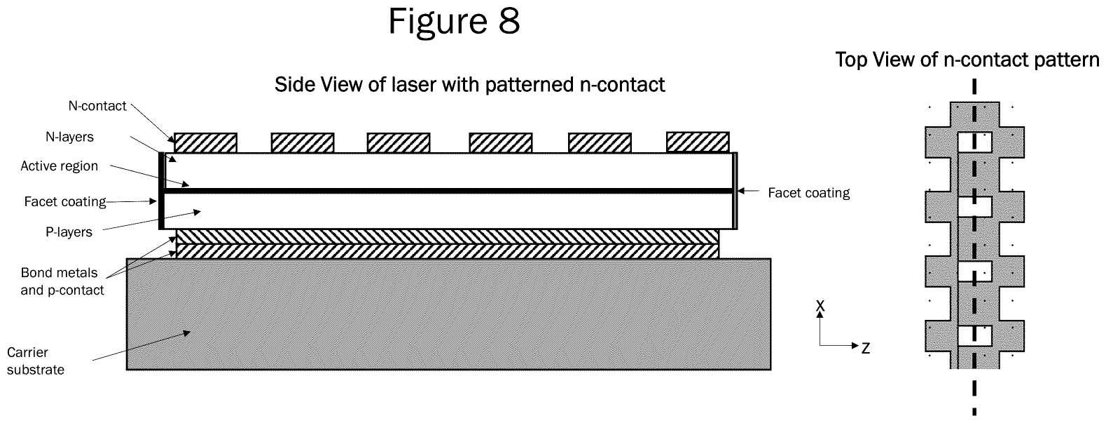

FIG. 8 is a simplified side-view diagram of a laser diode according to an example of the present invention. As shown is a laser device containing a gallium and nitrogen containing material. The device has a carrier substate member comprising a front side and a back side. The carrier substrate can be silicon, silicon carbide, gallium nitride, sapphire, any other materials, or combinations. The device has a metal bonding material overlying the front side of the substrate member. The bonding material is configured to bond an overlying transferred material to the front side of the carrier substrate. In a preferred example, the bond is metal to metal using high conductive metal such as gold, silver, or any combination, and others. In an example, the device has a p-type contact region overlying the metal bonding material to form a thermal path and an electrical path to and from the metal bonding material. The device has a p-type gallium and nitrogen containing region overlying the p-type contact region.

In an example, the device has an active region overlying the p-type gallium and nitrogen containing region. The active region comprises a plurality of quantum well regions. The device has an n-type gallium and nitrogen containing region overlying the active region. In an example, the n-type gallium and nitrogen containing region comprises a plurality of sub-regions numbered from 1 to N, where N is an integer of 2 and greater.

In an example, the device has a cavity region configured from a portion of the n-type gallium and nitrogen containing region. The cavity region having a first facet and a second facet. Each of the facets can be etched or cleaved. A coating is applied to each facet. The coating can be reflective or anti-reflective depending upon the application. As shown, the cavity region is formed between the first facet and the second facet and configured to propagate electromagnetic radiation through the cavity region and output a laser beam from one of the first facet or the second facet.

The device has a stripe region configured from an upper surface of the cavity region. In an example, an n-type contact region overlying the stripe region.

The device has a spatial pattern disposed on the n-type contact region and configured with a dimension and a geometry to achieve a predetermined mode quality (“M2”).

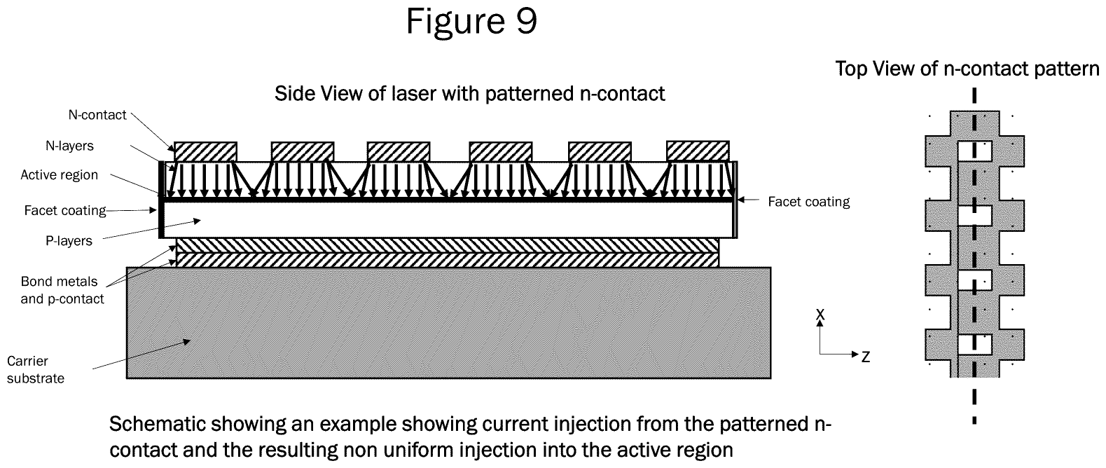

FIG. 9 is a simplified side-view diagram of a laser diode according to an example of the present invention. As shown, current injection from an n-type patterned contact region is illustrated. The n-type patterned contact region is selectively configured to achieve a desired spatial pattern for current injection into the active region. Such current injection allows the laser device to be operable in selected modes.

In other examples, the present invention provides a taped waveguide laser device. In an example, a tapered section can be gain guided or index guided. In an example of a gain guided, the tapered section is designed by an injection area in shape of taper with flared angle close to free diffraction of a single lateral mode from a straight section. In an example, the index change is configured by a change in gain in the tapered section due to injection on taper section. The gain guided taped section leads to low beam divergence at high powers. For the index guided, the taper section is designed by index contrast between a semiconductor and its surroundings in general by a ridge etched waveguide. An angle of the taper is designed to maintain and expand the single lateral mode operation and amplify its power.

In an example, the present techniques take careful consideration of the complex spatial-spectral dynamics in semiconductor laser diodes are necessary, due to the non-linear effects such as mode filamentation, spatial-hole burning, and thermal lensing. At high powers, the non-linear effects can be a challenge. It is possible to reduce or minimize the non-linear effects by reducing the confinement factor of the waveguide, resulting in high beam quality maintained at higher powers. It is also possible to reduce or minimize these effects by counter-acting them with the addition of patterned electrodes on the taper section. By independently controlling the current injection between the straight section and taper section, one can control the output power verses beam quality. Tapered laser diodes result in high power and beam quality laser with a penalty in efficiency due to the add extra loss during feedback between straight section and taper section.

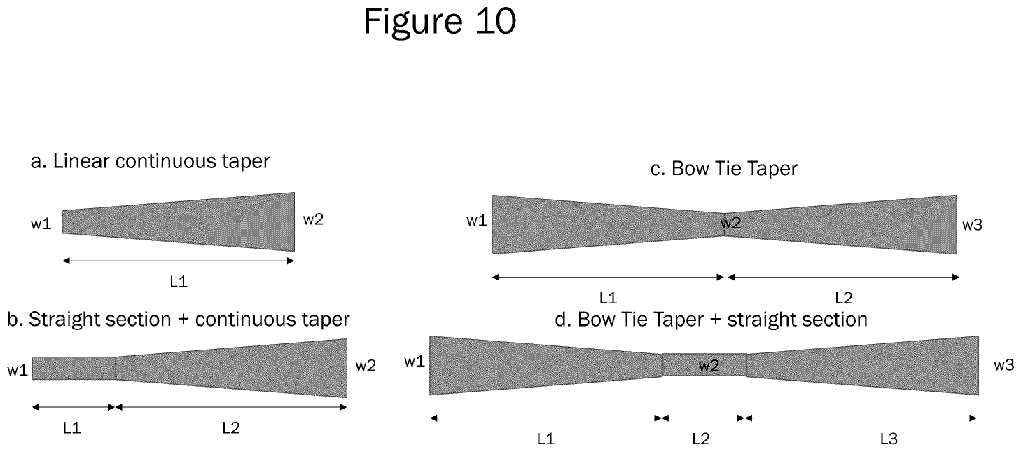

FIG. 10 is a simplified top-view diagram of a tapered waveguide laser device according to an example of the present invention. In an example, the present tapered waveguide laser device is configured for improved mode quality, M2. A tapered structure filters higher order lateral modes in the laser to reduce the number of active modes. Proper tapered designs can be used to achieve single lateral mode operation. As shown, several topic view schematics of tapered waveguide laser geometries are illustrated, but not intended to be comprehensive. In an example, the lateral width tapers can be linear tapers as shown below, can be exponential tapers, can be adiabatic tapers, or can be some combination thereof.

Various sizes are also illustrated. In A, w1 can range from about 1 um to about 10 um, and w2 can range from about 5 um to about 100 um or greater. L1 can range from 500 um to 5 mm. In B, w1 can range from about 1 um to about 10 um, and w2 can range from about 5 um to about 100 um or greater. L1 can range from 50 um to about 1 mm and L2 can range from 500 um to 5 mm. In C, w1 and w3 can range from about 5 um to about 100 um, and w2 can range from about 1 um to about 10 um or greater. L1 and L2 can range from 300 um to about 3 mm. In D, same as C, but L2 can range from about 5 um to about 500 um. Of course, there can be variations.

In an example, tapered laser diodes (or flared unstable cavity lasers) can be designed to provide high brightness, e.g., high power plus good beam quality. A tapered laser diode includes at least a straight narrow ridge waveguide section providing a single lateral mode combined with a tapered section designed to maintain single lateral mode while amplifying power of the diode.

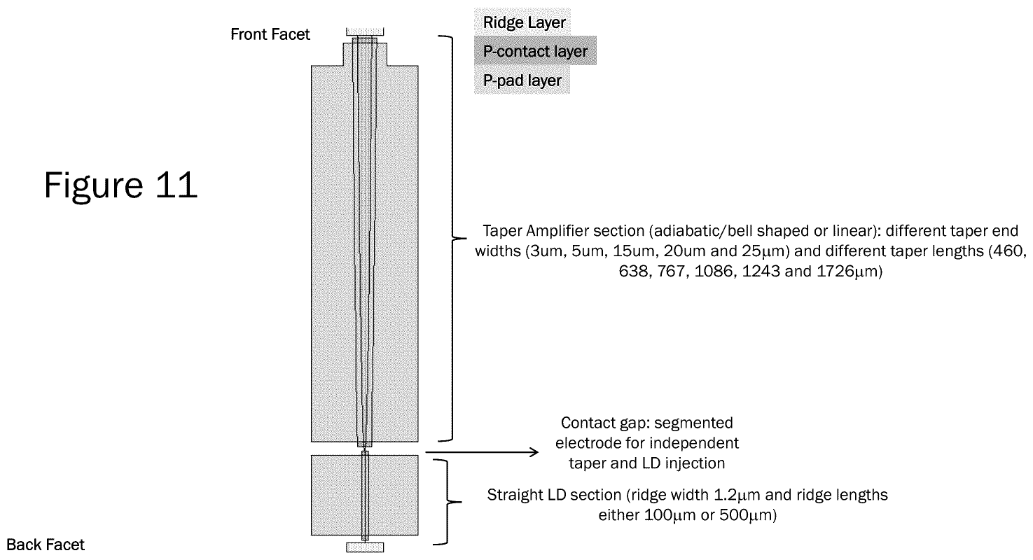

FIG. 11 is a simplified top view diagram of a straight laser diode configured with a tapered waveguide laser diode according to an example of the present invention. In an example, the straight and/or tapered laser diode is configured with patterned contact regions. As shown, a tapered amplifier section (e.g., adiabatic/bell shaped or linear) has various tapered end widths, e.g., 3 um, 5 um, 15 um, 20 um and 25 um, and various tapered lengths, e.g., 460, 638, 767, 1086, 1243 and 1726 um. In an example, end widths can be much larger, all the way to 50 um and above, and 100 um and above. In an example, lengths can range up to 5 um.

A contact gap between the tapered amplifier section and the straight laser diode can be a predefined length, e.g., 4 um, to form a segmented electrode for the independent tapered structure and laser diode injection. The gap ranges from about 2 um to about 20 um, but can be others.

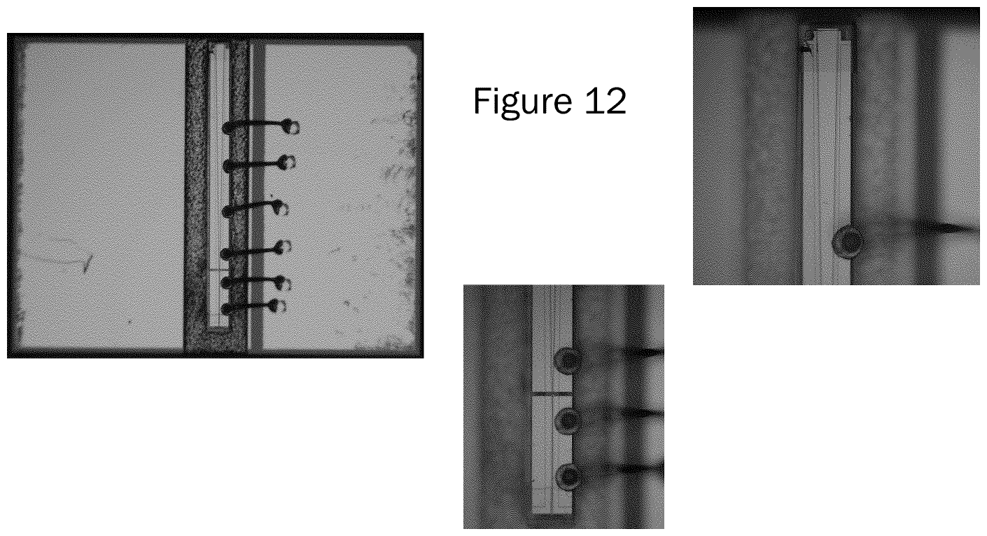

FIG. 12 is a simplified illustration of images of tapered waveguide laser diodes according to an example of the present invention. As shown, top view images include tapered waveguide structure, and overlying patterned contact region, which is configured on n-type material. A plurality of conductors in the form of wires couple the patterned contact region to a bus bar region.

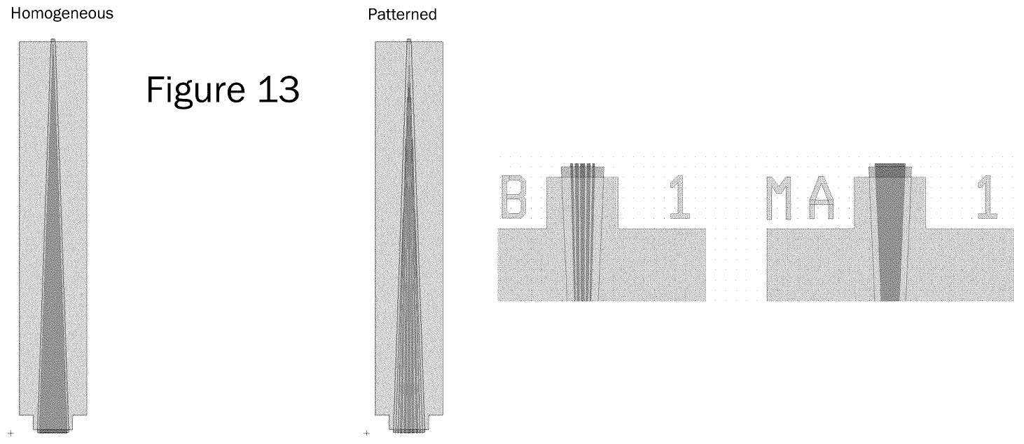

FIG. 13 is a simplified illustration of mask devices for a tapered waveguide laser diode according to an example of the present invention. Various mask devices are shown, including a homogeneous design and a patterned design in examples.

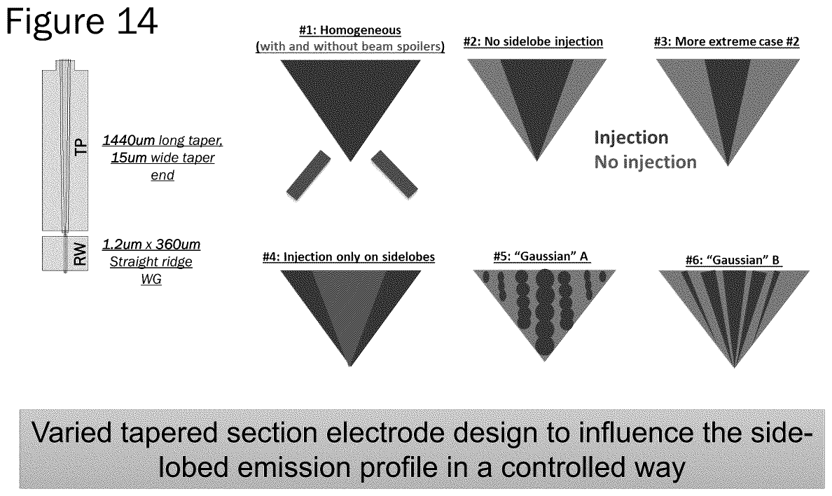

FIG. 14 is a simplified illustration of various patterned contact regions of tapered waveguide laser diodes according to examples of the present invention. A straight waveguide laser diode is configured with a tapered amplifier waveguide illustrated on a left side of the illustration. Shown are various patterned contact regions configured as electrode devices. In an example, a selected pattern is configured to achieve a predetermined side lobe emission pattern in a desired manner. The patterned contact regions configured on a tapered waveguide can be configured with an n-type region overlying an active region of the laser diode to achieve a predetermined current injection pattern into the active region.

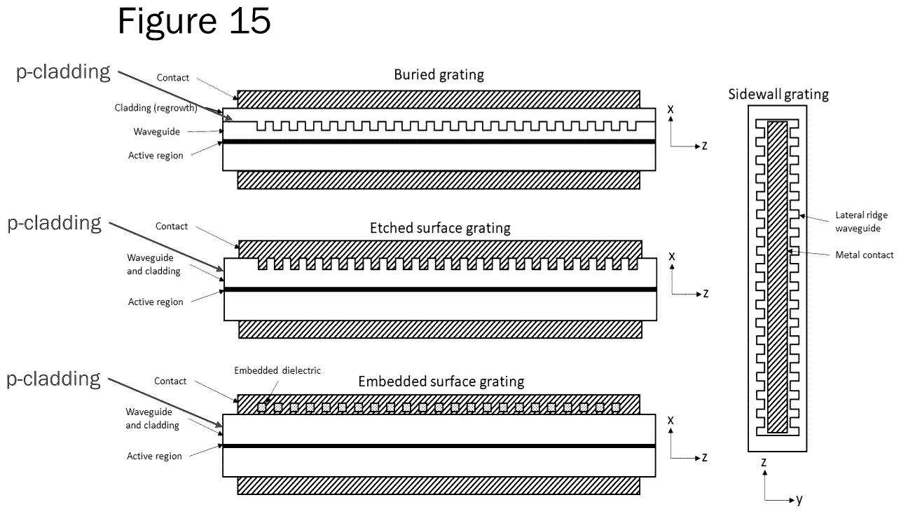

FIG. 15 is a simplified illustration of a distributed feedback laser diode device according to an example of the present invention. As shown, the invention includes a distributed feedback laser diode device. The grating for the distributed feedback can be etched, buried, or embedded, each of which is configured on a laser diode device with an n-type region that is disposed in an upside configuration, while the p-type region is within a vicinity of a carrier substrate.

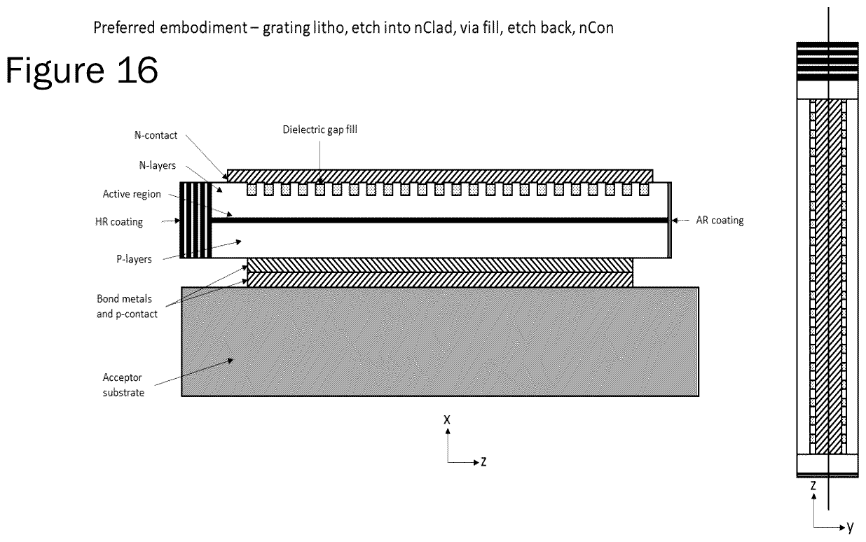

FIG. 16 is a simplified illustration of a distributed feedback laser diode device according to an alternative example of the present invention.

In a preferred example, the distributed feedback laser diode device has patterned n-type contact regions. Preferably, the patterned contact regions are combined with an underlying n-type gallium and nitrogen containing structure to selectively provide current injection into an active region to achieve desired performance for the laser diode device.

As background, multimode semiconductor GaN laser diodes with >4 W output have been available. However, single-lateral-mode GaN lasers that can operate at such power levels have not been realized and are typically limited to below 500 mW. Even further, single frequency GaN lasers at any power are not commercially available. Demand is rapidly accelerating for high-power, compact, reliable single-mode semiconductor lasers for applications including lidar, medical, laser pumping, defense and security, industrial such as welding, cutting, engraving, and 3D printing, Raman spectroscopy, and applications like nuclear fusion. Single-lateral mode lasers offer higher beam quality or M² values, which improve the brightness and efficiency of optical coupling such as fiber coupling. High power single-mode and single-frequency GaN lasers operating in the visible wavelength range with multi-watts, 100's of watts, kilowatts, or higher power with high beam quality can offer many advantages over the relatively low power (<500 mw or <1 W) single-lateral-mode GaN lasers that are commercially available in the market, which do not operate with single frequency.

In the present example, we introduce a monolithic MOPA device or tapered laser device that provides single-lateral mode, or single longitudinal mode for single-frequency operation at high power (>1 W). The output of the high-power single frequency devices can be aggregated by beam combining in many configurations. In one configuration, the devices are spatially combined, and/or polarization combined, and/or wavelength combined, or some combination thereof. In one example, single-frequency MOPA devices or tapered laser devices are beam combined using a phase locked approach to aggregate power.

In this present invention, we introduce a novel monolithic master oscillator power amplifier (MOPA) in the form of a single-lateral-mode, and optionally, single frequency, seed laser with a tapered amplifier to amplify the emission from the seed laser that can reach single-mode or single-frequency power levels of more than 1 W, more than 2 W, more than 4 W, more than 6 W, or more than 10 W single-longitudinal-mode operation. The MOPA device includes a single lateral mode, narrow waveguide width (1 um to 3 um), master oscillator or seed laser with an optional Bragg reflector such as distributed feedback laser for single frequency operation. The seed laser can range in length from about 50 um to about 2 mm. The seed laser is monolithically coupled to a tapered waveguide amplifier region where the waveguide width is increased over predetermined length to greater than 5 um, greater than 15 um, greater that 30 um, greater than 50 um, or greater than 100 um. The waveguide length can be longer than 500 um, longer than 1 mm, longer than 1.5 mm, longer than 2 mm, or longer than 3 mm.

In other examples the device is configured as a tapered laser device that can reach single-mode or single-frequency power levels of more than 1 W, more than 2 W, more than 4 W, more than 6 W, or more than 10 W single-longitudinal-mode operation. The tapered laser device includes a single lateral mode, narrow waveguide width (1 um to 3 um), section with a Bragg reflector and at least one tapered waveguide region where the waveguide width is increased over a predetermined length to greater than 5 um, greater than 15 um, greater that 30 um, greater than 50 um, or greater than 100 um. The waveguide length can be longer than 500 um, longer than 1 mm, longer than 1.5 mm, longer than 2 mm, or longer than 3 mm.

This invention enables a GaN-based manufacturable, robust, and reliable MOPA or tapered laser with single mode and/or single frequency at these power levels. In some examples the GaN MOPA device or tapered laser device is configured to operate with a single lateral mode. In other examples the GaN MOPA device or tapered laser device is configured to operate with single-longitudinal mode. In other examples the GaN MOPA device or tapered laser device is configured to operate both with single lateral mode and single longitudinal mode to enable a single frequency GaN device. The GaN MOPA or tapered laser device can be configured to operate at a peak emission wavelength of 395 nm to 450 nm, 450 nm to 500 nm, or 500 nm to 550 nm, or longer than 550 nm. The MOPA or tapered laser is a monolithically integrated photonic device capable of true single-mode output at high power. It includes a master oscillator section consisting of a seed laser with an integrated Bragg reflector and a power amplifier section. The MOPA device or tapered laser device is unique because it is a high-power, single monolithic device, making it compact and low-cost to manufacture in volume. Further details of the MOPA device and related techniques are described throughout the present specification and more particularly below.

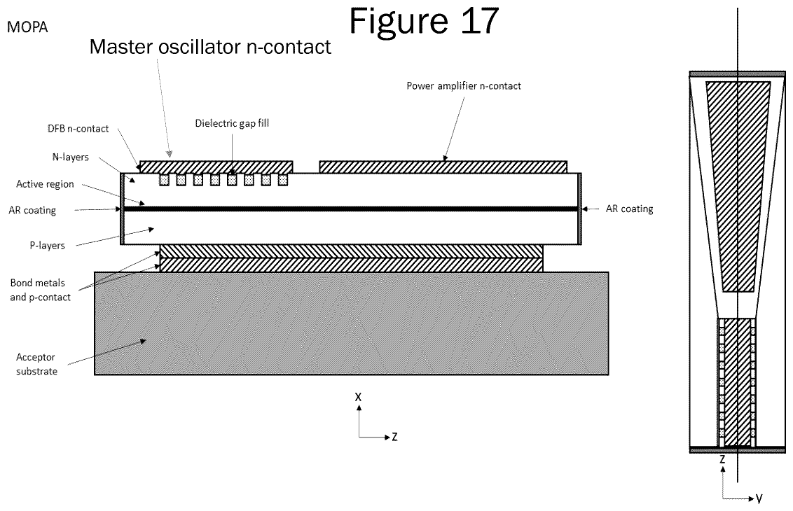

FIG. 17 is a simplified side-view diagram of a MOPA device according to an example of the present invention. As shown, the device has a master oscillator device coupled to an amplifier device, which is configured on a tapered cavity region. The master oscillator device is formed on a cavity with a constant width. Other elements are also shown. A technique for manufacturing the MOPA device can be found in U.S. Patent Application Publication No. US-2022-0344476, commonly assigned, and is hereby incorporated by reference herein.

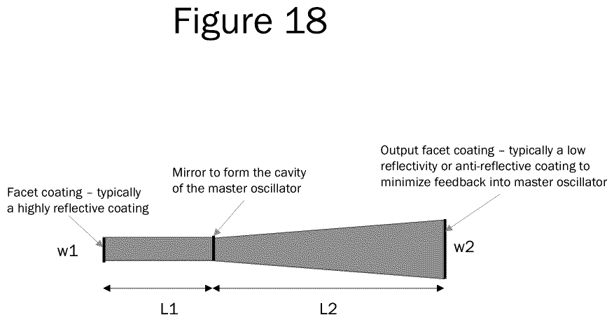

FIG. 18 is a simplified top-view diagram of a MOPA device configured with a tapered amplifier according to an example of the present invention. The MOPA device includes a single lateral mode, narrow waveguide width (1 um to 3 um, or more), master oscillator or seed laser with a length of L1. The seed laser can range in length, L1, from about 50 um to about 3 mm. The seed laser is configured with a cavity that has feedback through end mirrors to form a Fabry Perot resonator or through other types of mirrors. The master oscillator is electrically injected with current through an n-type and a p-type electrode to create gain and achieve lasing. The master oscillator is monolithically coupled to a tapered waveguide amplifier region such that the output from the oscillator is fed into the amplifier region to increase the power level of the output. The amplifier typically has a waveguide width that is increased over predetermined length, L2. The waveguide length, L2, can be longer than 500 um, longer than 1 mm, longer than 1.5 mm, longer than 2 mm, or longer than 3 mm. Over this length the width can increase to greater than 5 um, greater than 15 um, greater that 30 um, greater than 50 um, or greater than 100 um at the output facet. For higher reliable power levels, the width is increased appropriately. For example, for a reliable continuous wave power of 5 W a width of greater than 40 or 50 um may be desired at the output facet. The amplifier region is electrically biased independent from the master oscillator region. The higher the current injected to the power amplifier the higher the gain and higher the output power. In some configurations of the present example a patterned contact is used in the power amplifier to preserve mode quality.

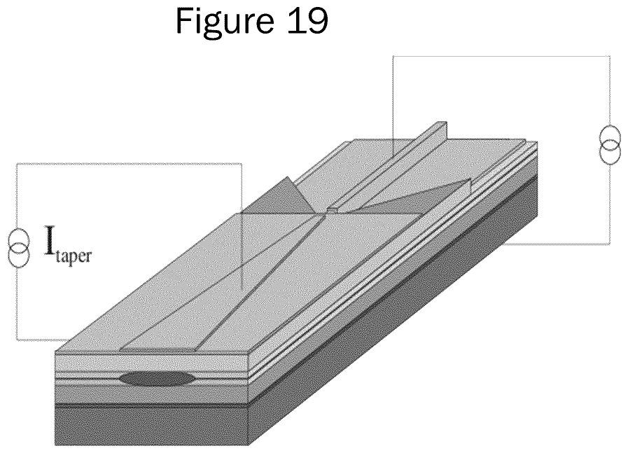

FIG. 19 is a simplified perspective-view diagram of a MOPA device according to an example of the present invention. As shown is an example of a perspective view of a tapered laser diode device. In an example, the waveguide tapered structure is configured with an n-type region side facing up on the device.

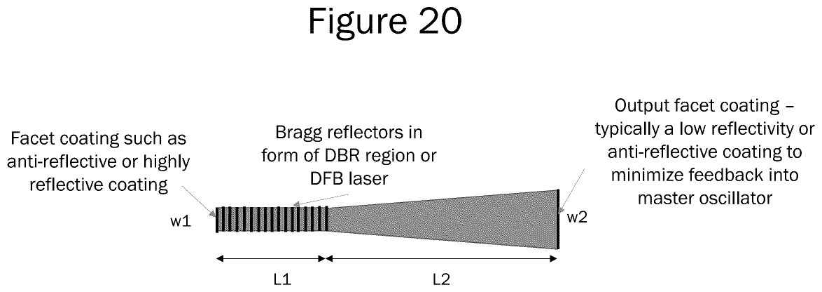

FIG. 20 is a simplified top-view diagram of a MOPA device configured with a single frequency according to an example of the present invention. As shown, the MOPA device includes a single lateral mode, narrow waveguide width (1 um to 3 um, or more), master oscillator or seed laser with a length of L1. The seed laser can range in length, L1, from about 50 um to about 3 mm. The seed laser is configured with a cavity that has feedback through Bragg reflectors such as distributed reflector regions inside the laser cavity and end mirrors or with a distributed feedback (DFB) laser configuration to create a single frequency or single longitudinal mode operation.

In an example, the master oscillator is electrically injected with current through an n-type and a p-type electrode to create gain and achieve lasing. The master oscillator is monolithically coupled to a tapered waveguide amplifier region such that the output from the oscillator is fed into the amplifier region to increase the power level of the output. The amplifier typically has a waveguide width that is increased over a predetermined length, L2. The waveguide length, L2, can be longer than 500 um, longer than 1 mm, longer than 1.5 mm, longer than 2 mm, or longer than 3 mm. Over this length the width can increase to greater than 5 um, greater than 15 um, greater that 30 um, greater than 50 um, or greater than 100 um at the output facet. For higher reliable power levels, the width is increased appropriately at the output facet. For example, for a reliable continuous wave power of 5 W a width of greater than 40 or 50 um may be desired. The amplifier region is electrically biased independent from the master oscillator region. The higher the current injected to the power amplifier the higher the gain and higher the output power. In some configurations of the present example a patterned contact is used in the power amplifier to preserve mode quality.

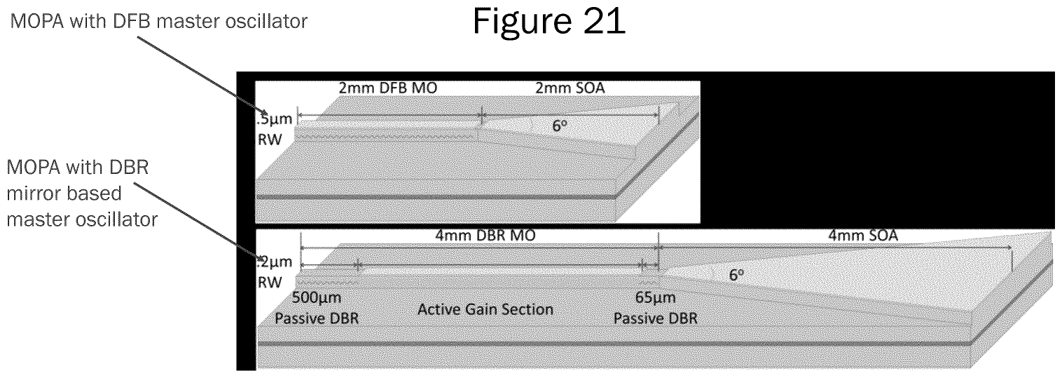

FIG. 21 is a simplified top-view diagram of a MOPA device configured with a distributed feedback reflector and a distributed Bragg reflector according to an example of the present invention. As shown, the MOPA device can have gratings for the distributed feedback reflector or a distributed Bragg reflector.

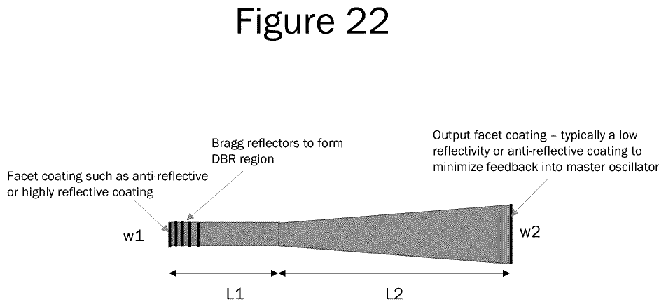

FIG. 22 is a simplified top-view diagram of a single frequency taped laser diode device configured with a distributed feedback reflector according to an example of the present invention. As shown, the tapered laser device includes a single lateral mode, narrow waveguide width (e.g., 1 um to 3 um, or more) single mode region with a length, L1, and a tapered waveguide region with a length L2. The narrow waveguide single mode region can range in length, L1, from about 50 um to about 3 mm and can be configured with a Bragg reflector region such as distributed reflector region to create a single frequency or single longitudinal mode operation. The tapered waveguide region has a waveguide width that is increased over predetermined length, L2. The tapered waveguide length, L2, can be longer than 500 um, longer than 1 mm, longer than 1.5 mm, longer than 2 mm, or longer than 3 mm. Over this length the width can increase to greater than 5 um, greater than 15 um, greater that 30 um, greater than 50 um, or greater than 100 um. For higher reliable power levels, the width is increased to appropriately levels at the output facet. For example, for a reliable continuous wave power of 5 W a width of greater than 40 or 50 um may be desired.

In an example, the amplifier region is electrically biased independent from the master oscillator region. The higher the current injected to the power amplifier the higher the gain and higher the output power. The tapered laser is electrically injected with current through at least one set of n-type and a p-type electrodes to create gain and achieve lasing. In some preferred examples there can be more than one set of electrodes along the cavity to independently tune the electrical injection and gain along the length of the tapered laser. For example, there may be 2 or more sets of electrodes in the single mode waveguide region and 2 or 3 or 4 or more sets of electrodes along the tapered region. In some examples of the single frequency tapered laser, there are multiple sections with Bragg gratings including Bragg gratings in the tapered waveguide regions. In some examples the Bragg gratings are configured along the entire cavity or along a majority of the cavity. In some configurations of the present example a patterned contact is used in the power amplifier to preserve mode quality.

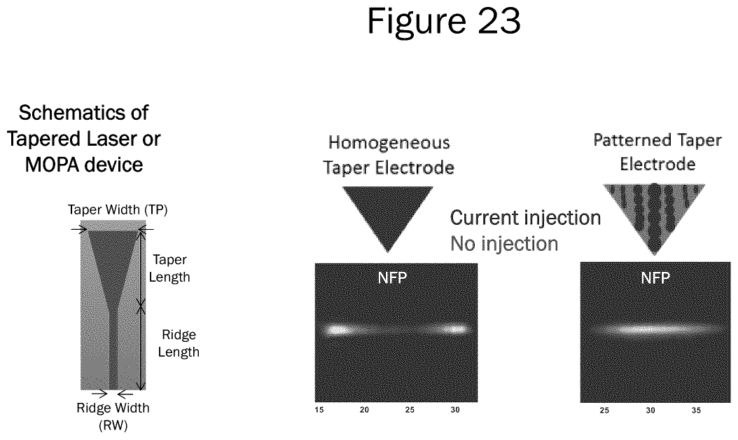

FIG. 23 illustrates a MOPA or taped waveguide laser device configured with various patterned contact regions according to an example of the present invention. As shown, patterned contact regions (e.g., electrodes) are implemented on a taper section, p-side down. Also shown is an Indication that mode profile is more homogeneous with modulation of current/gain in active region due to patterning of the contact regions.

According to the present invention using the gallium nitride transfer technology, arrays of lasers or MOPAs can be configured on “laser bars” wherein N tapered lasers or MOPA are positioned adjacent to each other on the same chip to form a bar. On the laser bar, the number of emitters, N, can range from 2 to 100 and they can be spaced by about 25 um to about 500 um, but of course there could be others. The individual emitters can be electrically connected in series or connected in parallel, and in some examples, there can be a series parallel configuration where certain groups of lasers are connected in series, and then these groups are connected in parallel with other series connected groups. By designing the electrical connections different current and voltage operating regimes can be achieved. For example, by connecting high power GaN tapered lasers in parallel, the drive electronics would need to source high current levels of about 5 to 30 amperes and low voltages of about 1 to 4 volts. However, if the 5 emitters were connected in series, the drive current maybe 1 to 6 amperes with a drive voltage of 12 to 25V. Further details of techniques for forming arrays of laser bars can be found throughout the present specification and more particularly below.

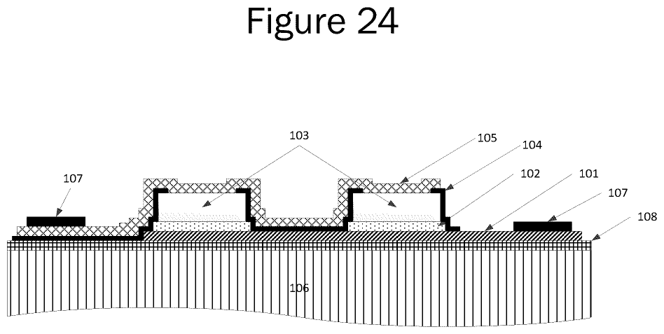

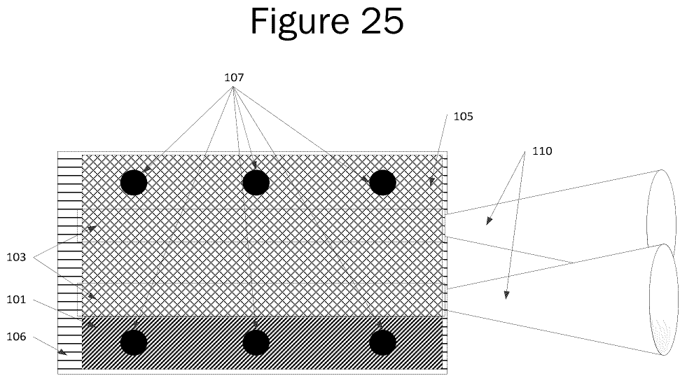

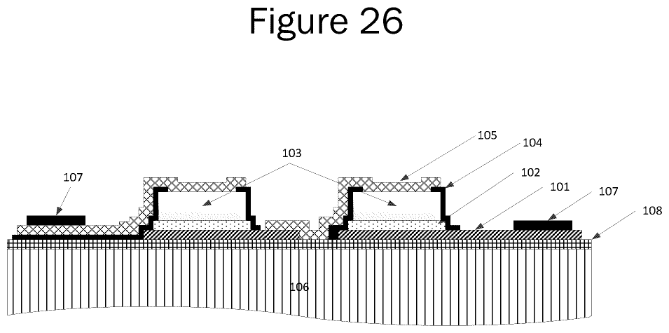

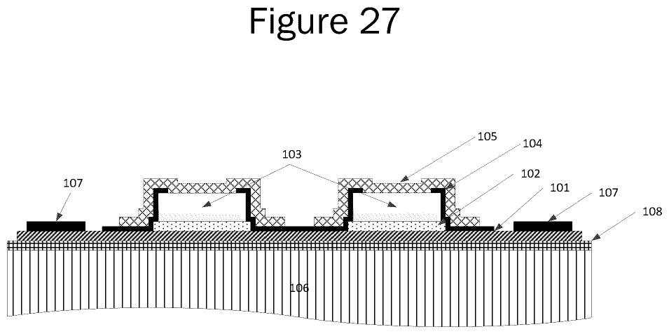

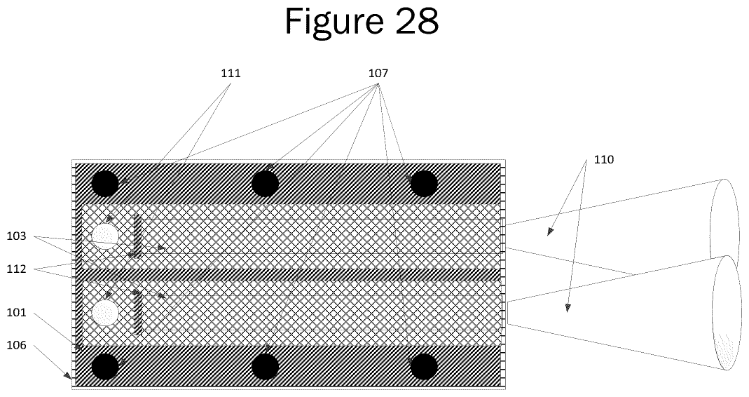

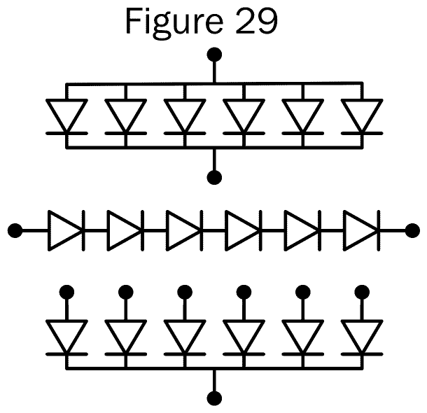

FIGS. 24 to 29 illustrate various view of an array of lasers or MOPAs that are configured as laser bars. As shown, FIG. 24 is a schematic cross-section of one embodiment of a multiple emitter laser device according to this invention wherein the laser stripes are electrically connected in parallel. FIG. 25 shows a top-view schematic of the embodiment of a multiple emitter laser device shown in FIG. 24 according to this invention. FIG. 26 is a schematic cross-section of an embodiment of a multiple emitter laser device according to this invention wherein the laser stripes are electrically connected in series. FIG. 27 is a schematic cross-section of an embodiment of a multiple emitter laser device according to this invention wherein the laser stripes are electrically individually addressable. FIG. 28 shows a top-view schematic of the embodiment of a multiple emitter laser device shown in FIG. 26 according to this invention. FIG. 29 shows schematic of electrical equivalent circuits for the three embodiments of multiple emitter laser device shown in FIG. 25, FIG. 26, and FIG. 27 according to this invention. Further details on such laser bars including a method of manufacture can be found in U.S. Patent Application Publication No. US-2021-0344164, commonly assigned and hereby incorporated by reference in its entirety herein.

In an example, the present laser devices can be configured in a system for high power applications. As an example, single emitter GaN lasers can generate greater than 3 W, greater than 5 W, and greater than 8 W, but in many applications such as industrial welding, cutting, or 3D printing, much higher total power is desired. In these applications various approaches are used for beam combining. The laser beams from separate discrete laser beams can be combined, and/or the N beams from a laser bar with N emitters are combined. For example, if 20 5 W lasers are beam combined, a total of 100 W can be achieved in the combined beam. In certain applications, it is important that brightness is maximized by combining the laser beams into a final beam that has a minimized diameter or size or into a fiber with a minimized fiber core diameter such as 50 um, 100 um, 200 um, 400 um or larger fiber core diameter.

As noted, beam combining the output of laser bars is efficient because the emitters are spatially arranged with a very tight and compact tolerance based on the lithographic process steps that are used to define the laser stripes. This enables more efficient collimation of the laser beams prior to beam combination since optical elements such as micro lens arrays can be aligned to all the emitters in the laser bar in one alignment sequence whereas if the beams of individual lasers are being combined, the alignment sequence must be performed for each emitter. That is, for a laser bar that has 20 emitters, the 20 emitters can be optically collimated much more efficiently than collimating 20 separate discrete lasers. Since this optical collimation process typically requires an active alignment process, it can be time consuming and contribute substantial overall cost to the process.

In this invention, tapered laser bars or MOPA device bars may be optically collimated and beam combined using a system approach. In a preferred example of the present invention, single frequency MOPA devices or tapered lasers are configured in a bar with N emitters, optically collimated, and beam combined using one or more beam combining methods.

There are several approaches that can be used to combine the optical output laser beams from the tapered laser devices or MOPA devices, wherein beam combining can be performed on individual discrete tapered lasers or MOPA devices and or from tapered laser bars or MOPA device bars, or some combination thereof.

In a first beam combining method, the output laser beams from the tapered lasers or MOPA devices according to the present invention are spatially combined into a single collimated beam or into a waveguide device such as an optical fiber. Spatial beam combining, sometimes called side by side combining, deploys an optical pathway configuration wherein the output from 2 or more laser devices are collimated in the slow and or fast axis directions, and then the 2 or more collimated laser beams are configured with an optical pathway that results in adjacent parallel propagation. This is often done with a series of optics such as fast axis collimating lenses, slow axis collimating lenses, micro lens arrays, spherical lenses, turning mirrors, dichroic mirrors, and some sort of spatial difference between each laser device such as the mounting height, or z-alignment. This spatial difference dictates the relative position of each laser beam in the resulting beam of collimated co-parallel beams.

In a second beam combining method, the output laser beams from the tapered lasers or MOPA devices according to the present invention are polarization combined to form a polarization combined output beam.

In a third beam combining method, the output laser beams from the tapered lasers or MOPA devices according to the present invention are spectrally combined to form a spectrally combined output beam.

As used herein, the terms “first”, “second”, “third” or other numerical values do not imply any order, but can be interpreted broadly to differentiate each technique. Further details of the present techniques can be found in reference to the drawings below.

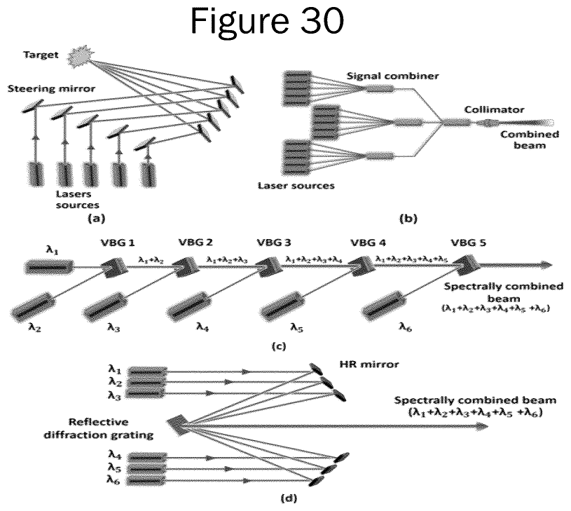

FIG. 30 illustrates schematic representation of four main methods of incoherent beam combining according to an example of the present invention. The methods include (a) spatial beam combining, side-by-side beam combining, (b) beam combining using all-fiber passive signal components, (c) spectral beam combining, SBC with volume Bragg gratings (VBG) as a wavelength-dependent transmission element, and (d) SBC with reflection diffraction grating as a dispersive optical element according to examples of the present invention.

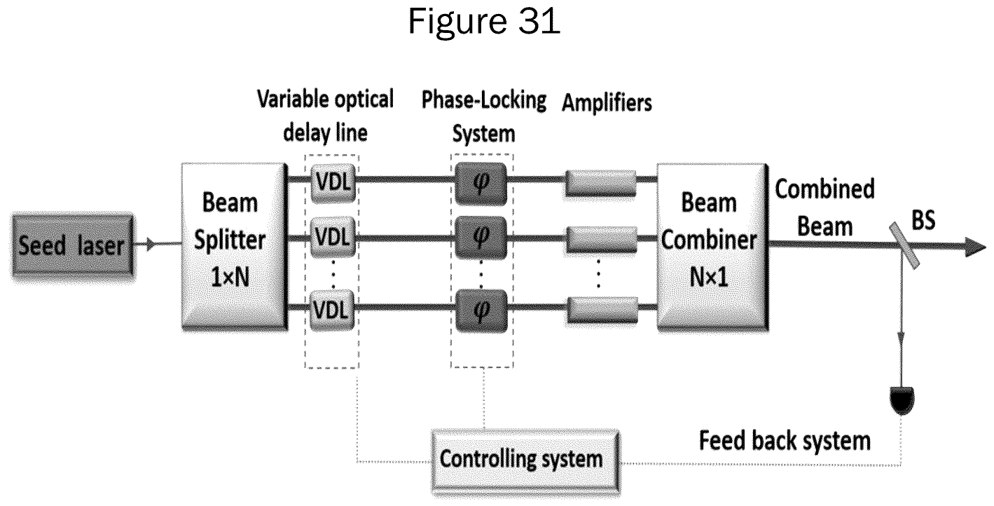

FIG. 31 is a simplified general schematic illustration of coherent beam combining (CBC) according to an example of the present invention. The CBC systems typically involve five principal parts: (i) the geometry of splitting/combining, (ii) laser sources and amplifying section, (iii) phase-locking system, (iv) optical path difference (OPD) control, and (v) number of channels. All of them will be discussed in detail in this section with the emphasis both on the concept and operation principles.

In some embodiments according to the present invention, a high-power laser system is formed by amplifying and aggregating the output of N high power single-mode or single-frequency GaN-based laser diodes. The output optical signal from the GaN based laser diode can be a continuous wave signal, a pulsed signal, or a combination thereof. One or more laser beam combination techniques can be implemented to aggregate or combine the laser beams and the combined laser beams can be further amplified. Incoherent beam combinations techniques, such as spectral beam combining, polarization beam combining, and spatial beam combining, can be implemented individually or in combination. In some embodiments, coherent beam combining is used to form the high-power laser system. In coherent beam combining, a single beam can be obtained with correspondingly higher power and with substantially preserved beam quality for increased radiance or brightness. Additionally, coherent combining can preserve spectral bandwidth. Combining would preferably occur to increase intensity of the beam without causing destructive interference between a pair of beams.

Spectral beam combining (or wavelength beam combining) is a technique to scale the total beam power by combining several high-power laser beams to obtain a single beam with correspondingly higher power and with a preserved beam quality for increased brightness. In spectral beam combining, several beams with non-overlapping optical spectra may be combined within some kind of wavelength-sensitive beam combiner such as prisms and/or diffraction gratings, which can deflect incident beams according to their wavelengths so that subsequently they all propagate in the same direction. Other approaches rely on optical components with wavelength-dependent transmissions, such as dichroic mirrors or volume Bragg gratings. In some approaches, the laser emitters are independently tuned to a particular wavelength, and their outputs are aligned to reach the beam combiner at the corresponding angle. In some embodiments, each emitter can automatically adjust its wavelength according to its spatial position. This principle is suitable for laser diodes in the form of diode arrays. Thermal effects of the wavelength-sensitive beam combiners may be considered in the design of the high-power laser system. For transmission gratings, thermal effects may be more severe, whereas reflection gratings can work at power levels of at least 100 kW because they absorb less power and can be cooled.

In polarization beam combining, two laser beams with linearly polarized light are combined. In one example, the output of one laser diode that is vertically polarized and another laser diode that is horizontally polarized are provided to a thin-film polarizer. In this configuration, one of the beams is reflected and the other is transmitted such that both beams then propagate in the same direction to form an unpolarized beam having the combined optical power and nearly double the brightness of the input beams.

Coherent beam combining can be classified into categories including side-by-side combining and filled-aperture. Side-by-side combining (tiled aperture) techniques may use a kind of phased array, leading to a larger beam size but reduced divergence. Filled-aperture techniques, where several beams are combined into a single beam with the same beam size and divergence, may use, for example, a grating splitter. In any case, mutual coherence of the combined beams is important. As a simplified example of side-by-side combining, four beams with flat-top intensity profiles of rectangular cross-section and flat phase profiles may be arranged to obtain a single beam with just two times the dimensions, or four times the area, and four times the power. If the beams are all mutually coherent, and the relative phases are properly adjusted to obtain essentially plane wavefronts over the whole cross-section, the resulting beam has a beam divergence that is only half that of the individual beams. As a result, the beam quality is preserved, and the brightness can be four times that of the single beams.

In addition to phase coherence, the combined beams can also have a stable linear polarization with reasonable amplitude fluctuations. There are several methods for obtaining mutual coherence. Mutually coherent single-frequency signals can be generated by splitting the output of a low-power single-frequency laser and amplifying the resulting beams such as in high-power fiber amplifiers. Since the amplifiers may introduce amplifier noise, particularly in the form of low-frequency phase disturbances, an active feedback stabilization scheme may be included. The resulting phase-coherent beams can then be combined either at multiple beam splitters or with a tiled-aperture approach. The latter may be more convenient for a larger number of beams. Such techniques may be applied particularly to arrays of fiber amplifiers, laser diodes, and/or ridge waveguide amplifiers.

Alternatively, the phases of multiple high-power lasers can be synchronized by optical coupling. One approach is coupling via evanescent waves (leaky-wave coupling) with the goal of exciting a suitable super mode of the structure that exhibits a high beam quality. This technique may be applied particularly to laser diode arrays containing multiple active waveguides on one chip, where coupling can be obtained simply by placing the waveguides sufficiently closely. A challenge is to obtain both tight coupling with phases that are equal rather than opposite at the outputs of the waveguides. This can be avoided with common-resonator techniques where the beams are fully combined at the output coupler but split within the resonator to be amplified in different gain elements.

For certain optical frequencies, there are super modes where the reflections from the different sub-resonators add in-phase at the output coupler. If such super modes lie within the gain bandwidth, lasing may occur only on those, resulting in efficient coherent beam combination. This method may be called self-organizing phase synchronization. It does not require interferometric stabilization of the optical path lengths and may be particularly suitable for fiber lasers. There are also schemes where phase synchronization is achieved using a nonlinear interaction such as stimulated Brillouin or Raman scattering.

Passive beam combining techniques can be deployed where the input lasers automatically obtain mutually coherent oscillation even though they are not single-frequency lasers. However, single-frequency operation is typically required for actively stabilized laser arrays.

Coherent beam combining can also be achieved with non-monochromatic input beams as long as they are mutually coherent. For example, ultrashort pulses having a broad optical spectrum can be coherently combined if the path lengths are matched such that the temporal peaks of the contributions of all input beams to the output occur at the same time. The broader the optical bandwidth the more important is delay matching.

A challenge with coherent beam combining is obtaining phase coherence at high power levels in a stable manner. Another challenge is the need to match wavefronts and polarization directions.

The high-power laser systems according to the present invention are configured with one or more high power beam combining techniques as described above. The N laser beams that are combined can be amplified laser beams that have been amplified by one or more amplifiers such as semiconductor optical amplifiers (SOA), fiber amplifiers, or other types of amplifiers. In an embodiment, a high-power single mode or single frequency tapered laser or MOPA device is configured as the source laser for one or more of the N laser beams to be combined. The beams originating from the source lasers may be fed through subsequent amplifiers such as one or more GaN based SOAs. The SOAs can be carefully designed to increase the saturation power or saturation energy such as low optical confinement factor SOAs or gain clamped SOAs. By reducing the optical confinement factor, amplified spontaneous emission (ASE) is suppressed for improvements to the saturation characteristics of the SOA. The suppression of ASE is beneficial for the efficient amplification of optical pulses since a high ASE intensity leads to a reduction in excited carriers in the conduction/valence bands through the stimulated emission process. In addition to the confinement factor, the SOA should have an optimized design including the gain characteristics, active region design, waveguide width, waveguide length, series resistance, propagation loss, and more.

In some embodiments, special types of laser diode sources, such as slab-coupled optical waveguide lasers (SCOWL), may be used with carefully designed waveguide and active region layers to achieve low confinement and low optical loss with high output powers of 1 W to 1 kW or more.

In some embodiments, one or more SOAs are included within the amplification stages of the high-power laser system. In addition to noise level and absolute gain, the saturation power of the SOA is important. To maximize the saturation power, the waveguide and active region of the SOA must have a large cross-section for the optical mode so that photons are spread out for a given power. Put another way, the optical confinement factor in the gain medium or quantum wells can be minimized. A small differential gain with a minimized gain medium (e.g., a quantum well) having a small cross-section will support higher saturation power. Additionally, a fast carrier lifetime, for the resupply of carriers to the gain medium, may be desirable. To achieve such properties, careful waveguide and active region design must be used. For example, the number of quantum wells can be reduced, the quantum wells can be made thin, the optical waveguide thickness can be optimized, and the quantum wells can be positioned with respect to the waveguide to minimize the optical confinement factor. In one example, a slab coupled optical waveguide amplifier (SCOWA) may be included in one or more of the amplification stages of the high-power laser system.

In some embodiments, the high power GaN-based laser diodes are configured as very high-peak-power optical pulse sources. These high-power pulses may be achieved, for example, with gain switching, self-pulsation, mode-locking, and other techniques. The output from the single-mode or single-frequency high power tapered lasers or MOPA devices can be fed through separate GaN-based SOA devices to amplify optical pulses, fiber amplifiers, other types of amplifiers, multi-stage amplifiers, or combinations of amplifiers to amplify the pulses generated by the GaN-based based laser diode such as a mode-locked laser diode (MLLD).

Mode locking is a technique by which a laser can be made to produce pulses of light of extremely short duration, on the order of nanoseconds, picoseconds, or femtoseconds. These pulses can be generated by active mode locking, passive mode locking, fundamental mode locking, harmonic mode locking, self-starting mode locking, additive-pulse mode locking, Kerr lens mode locking, hard/soft aperture mode locking, soliton mode locking, nonlinear mirror mode locking, or regenerative mode locking. In a mode locked laser, one or more pulses circulate in the laser resonator, where each time a pulse hits the output coupler an output pulse is emitted thus forming a regular pulse train. The pulse repetition rate is the inverse of the round-trip time in the laser resonator or an integer multiple of it in the case of harmonic mode locking.

Typically, the pulse duration is between 30 fs and 30 ps and in most cases is orders of magnitude shorter than the pulse spacing. Therefore, the peak power of a mode-locked laser can be orders of magnitude higher than the average power. Mode locking is achieved by using a mode locking device within the laser resonator cavity that can be either an active element such as an optical modulator or a nonlinear passive element such as a saturable absorber. In a steady state of a mode-locked laser, the pulse parameters (pulse energy, pulse duration, chirp, spectral bandwidth, etc.) are all unchanged after each completed round trip such that the various effects influencing the circulating pulse (e.g. laser gain and propagation losses, nonlinearities, and chromatic dispersion) must be in a balance. Active mode locking requires the periodic modulation of the resonator losses or alternatively of the round-trip phase change using a modulator such as an acousto-optic modulator, electro-optic modulator, Mach-Zehnder integrated-optic modulator, or a semiconductor electro-absorption modulator. In passive mode locking with a saturable absorber, much shorter (femtosecond) pulses are achieved because a saturable absorber can modulate the resonator losses much faster than an electronic modulator. In this configuration, the shorter the pulse becomes the faster the loss modulation. Hybrid mode locking can be achieved when active and passive mode locking are simultaneously applied. Such hybrid mode-locked lasers combine some key advantages, such as an externally controlled pulse repetition rate, relatively short pulses, and robust initiation of the mode-locked operation.

Conventional GaN-based mode locked laser diodes in MOPA structures have been shown to achieve 300 W. With the laser structure according to the present invention, much higher output powers can be achieved.

Very high-power laser systems may be achieved using the beam combining and laser operation techniques described above when applied to the novel GaN based laser and MOPA structures according to the present invention. The very high output power can be achieved in a continuous wave output mode or a pulsed output mode. In one example of a continuous wave high power laser system, 100 single frequency MOPA devices or taper laser devices output about 1 W to about 10 W of optical power with a wavelength in the 380 nm to 540 nm range. The output of each of these lasers is then fed through a first stage amplifier such as an SOA or fiber amplifier for 10 dB of gain to achieve an output of 10 W to 100 W in each beam. These beams are then amplified in a second stage amplifier with 10 dB of gain to achieve an output of 100 W to 1 kW in each beam. The 100 single mode or single frequency beams with 100 W to 1 kW are then combined using coherent beam combining to achieve a single beam with 10 kW to 100 kW. According to the present invention, multiple of these coherently combined laser units can be combined using spectral beam combining. In one example, 20 of these coherently combined laser units with 10 kW to 100 kW operating at different wavelengths in the range of 380 nm to 480 nm are combined using spectral beam combining to achieve a laser beam with about 200 kW to 2 MW. In one embodiment, two of these laser units with coherent beam combining and spectral beam combining can be further combined using polarization beam combining to achieve a system with 400 kW to 4 MW of continuous wave output power in the spectral range of 380 nm to 480 nm. In some embodiments, spatial beam combining can be applied to spatially beam combine multiple beams such as 20 beams to achieve a system outputting a laser beam with about 8 MW to 80 MW of power. This laser beam could then be further amplified to achieve even higher output powers. Of course this is just one example of combining various amplification and beam combining techniques of a continuous wave laser beam. In light of the embodiments disclosed herein, there could be many others including using different amplification techniques and/or using different numbers of amplification stages, including using amplification stages between different beam combining techniques and changing the order or the type of beam combining techniques.

In another example embodiment, an ultra-high-power pulsed laser beam may be achieved. In one example of a pulsed wave high power laser system, 100 single frequency mode locked laser diode devices such as a MOPA or tapered laser device can output a peak power of about 100 W to about 1 kW of pulsed peak optical power with a wavelength in the 380 nm to 540 nm range. The output of each of these lasers may be fed through a first stage amplifier such as an SOA or fiber amplifier for 10 dB of gain to achieve a peak pulsed output power of 1 kW to 10 kW in each beam. These beams are then amplified in a second stage amplifier with 10 dB of gain to achieve an output of 10 kW to 100 kW peak power in each beam. The 100 single mode or single frequency beams with 10 kW to 100 kW may be combined using coherent beam combining to achieve a single beam with 1 MW to 10 MW of pulsed peak output power. According to the present invention, multiple of these coherently combined laser units can be combined using spectral beam combining. In one example, 20 of these coherently combined laser units with 1 MW to 10 MW operating at different wavelengths in the range of 380 nm to 480 nm are combined using spectral beam combining to achieve a laser beam with about 20 MW to 200 MW. In one embodiment, two of these laser units with coherent beam combining and spectral beam combining can be combined using polarization beam combining to achieve a system with 40 MW to 400 MW of pulsed peak output power in the spectral range of 380 nm to 480 nm. In some embodiments, spatial beam combining can be applied to spatially beam combine multiple beams such as 20 beams to achieve a system outputting a laser beam with about 800 MW to 8 GW of pulsed peak power. This laser beam could then be further amplified to achieve even higher output powers. In light of the embodiments disclosed herein, there could be many others including using different amplification techniques and/or using different numbers of amplification stages, including using amplification stages between different beam combining techniques and changing the order or the type of beam combining techniques.

In some examples, amplifiers with higher gain or systems with more stages of amplification can be implemented to achieve higher pulsed peak output power. For example, peak powers of 10 or 100 GW can be achieved, or peak powers of 1 to 100 terrawatts (TW) can be achieved. In some examples, multiple laser systems generating such high peak powers can be combined. As an example, 100 to 1000 of these laser systems can be combined to direct 100 to 1000 times the power at a target. If 100 10 GW or 1 TW laser systems were combined, a total power at the target could be 1 TW to 100 TW.

In a pulsed laser system, the repetition rate, pulse width, and total energy in each pulse are important operating characteristics that are carefully selected and achieved through system design. The pulsed laser source can be designed and configured to operate with a repetition rate of 1 KHz to about 1 THz, or about 1 MHz to about 100 MHz, or about 100 MHz to about 10 GHz, or about 10GHz to about 1 THz, or about 1 THz to about 100 THz. This pulse width can range from about 1 ns to about 1 fs, or about 10 micro second to about 100 ns, or about 100 ns to about 10 ps, or about 10 ps to about 100 ps, or about 100 ps to about 10 fs. The total energy in the output beam pulse can be about 1 micro joule to about 10 joules, or about 1 micro joule to about 1 millijoule, or about 1 millijoule to about 100 millijoule, or about 100 millijoule to about 1 joule, or about 1 joule to about 100 joules.

In some embodiments, special cavity designs are included to establish a predetermined pulse width and repetition rate based on the system requirements. For example, the cavity length and index of refraction profile can be carefully designed. Additional active and/or passive elements can be inserted into the cavity to modify the pulse width or repetition rate, and other approaches of mode locking can be established.

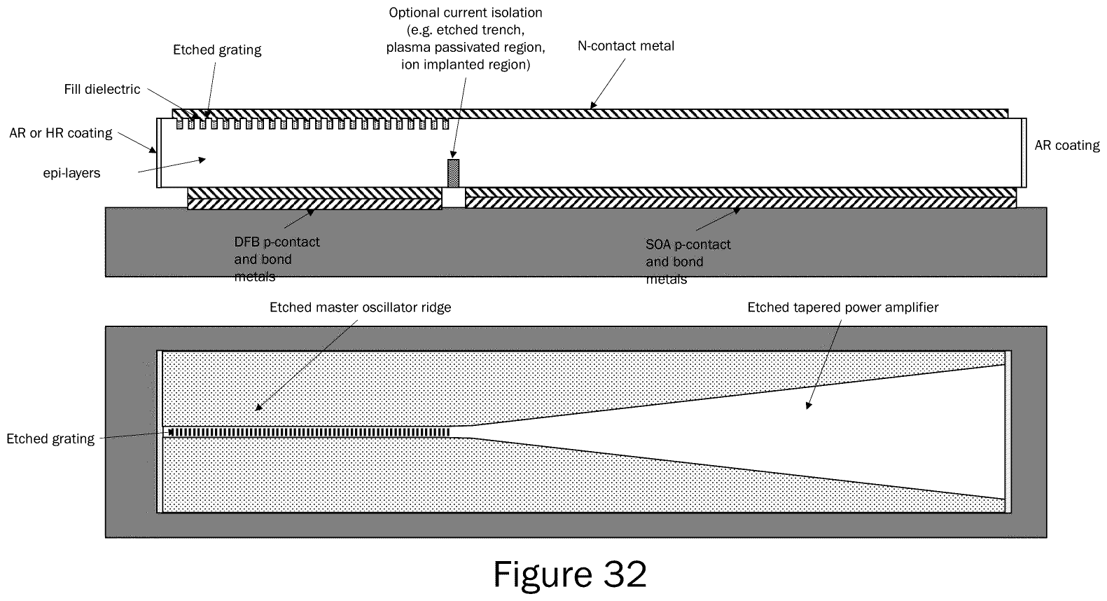

FIG. 32 includes simplified top-view and cross-sectional diagrams of a MOPA or laser diode device according to an example of the present invention. The device in this example includes an etched grating region and a tapered amplifier region. As with other embodiments described and/or shown herein, the tapered sections may be adiabatic/bell shaped or linear.

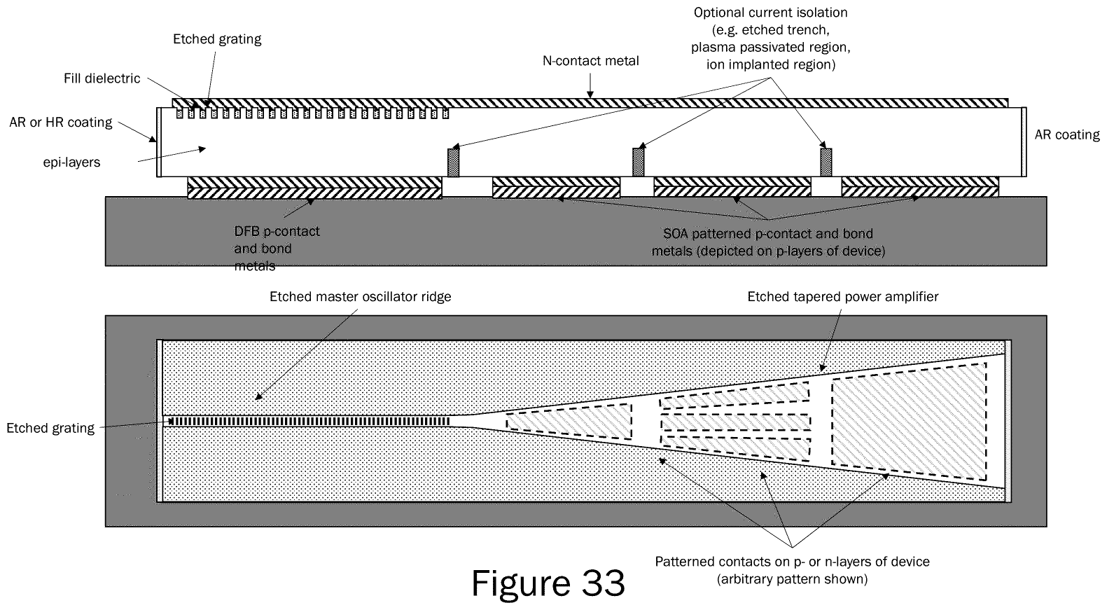

FIG. 33 includes simplified top-view and cross-sectional diagrams of a MOPA or laser diode device according to an example of the present invention. The device in this example includes an etched grating region and a tapered amplifier region. The etched grating region and/or a tapered amplifier region may be configured with patterned contacts. One or more current isolation features may be provided between the etched grating region and the tapered amplifier region. The current isolations features may be provided, for example, by an etched trench, a plasma passivated region, an ion implanted region, or the like.

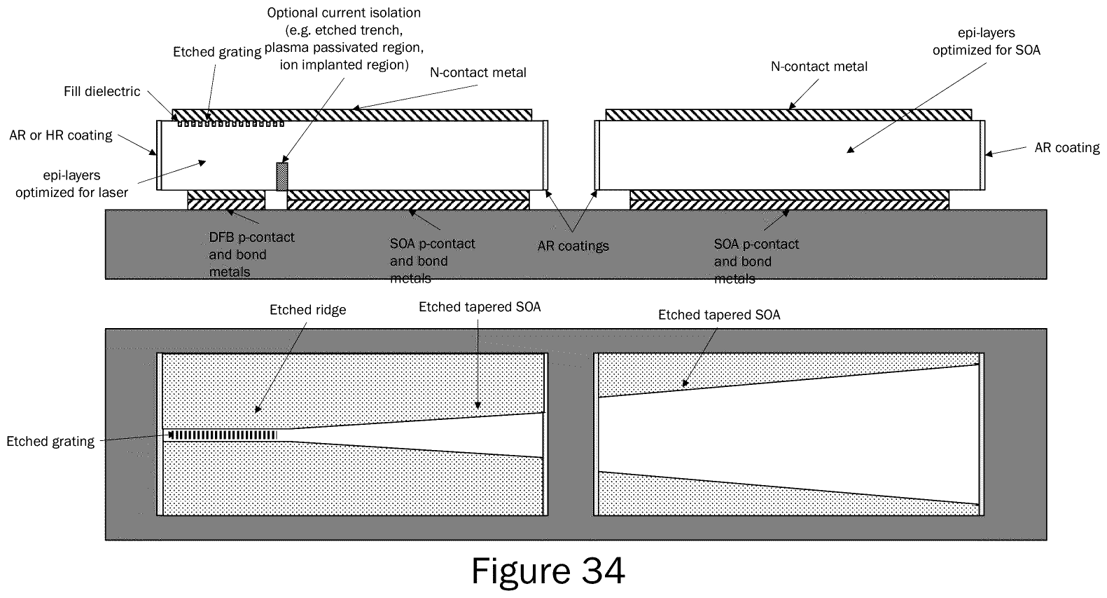

FIG. 34 includes simplified top-view and cross-sectional diagrams of a continuous mesa single-frequency MOPA or laser diode device with a separate mesa amplifier according to an example of the present invention. The MOPA or laser diode device and/or the separate mesa amplifier may be configured with patterned contacts. This example illustrates a single chip arrangement where one or both sides of the separate mesa amplifier may be AR coated. The separate mesa amplifier may have a different epi design, with modifications such as a lower confinement factor. A current isolation feature between the etched grating and the tapered region of the MOPA or laser diode device may be provided, for example, by an etched trench, a plasma passivated region, an ion implanted region, or the like. A gap is provided in this example between the MOPA or laser diode device and the separate mesa amplifier and may form a segmented electrode for independent injection.

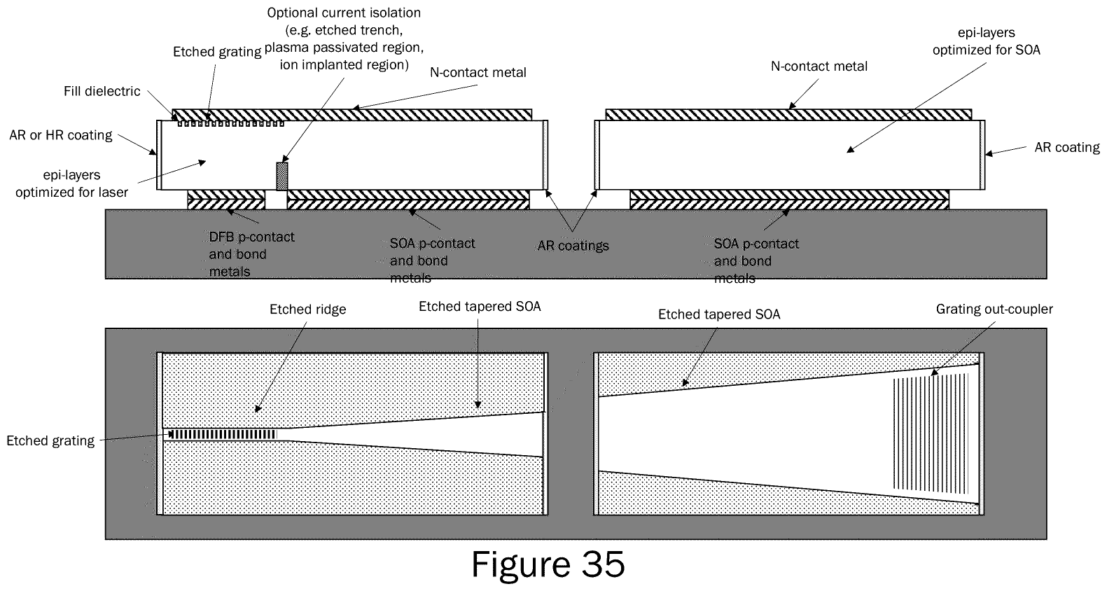

FIG. 35 includes simplified top-view and cross-sectional diagrams of a continuous mesa single-frequency MOPA or laser diode device with a separate mesa amplifier according to an example of the present invention. This example is similar to that of FIG. 34 with a grating out-coupler at an output of the separate mesa amplifier.

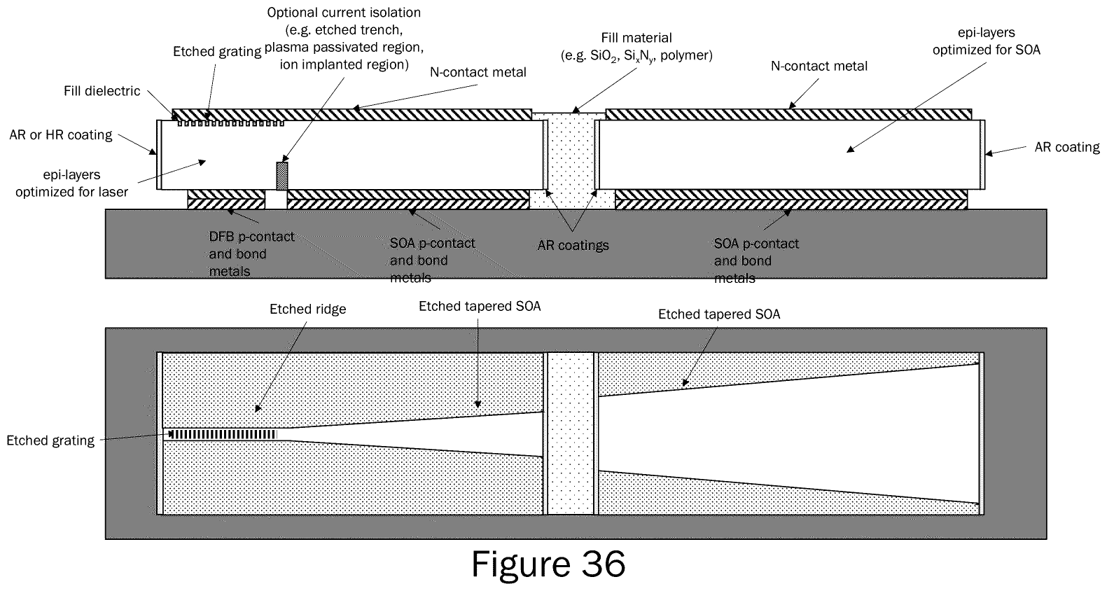

FIG. 36 includes simplified top-view and cross-sectional diagrams of a continuous mesa single-frequency MOPA or laser diode device with a separate mesa amplifier according to an example of the present invention. This example is similar to that of FIG. 34 with a fill material between the mesas to improve coupling efficiency.

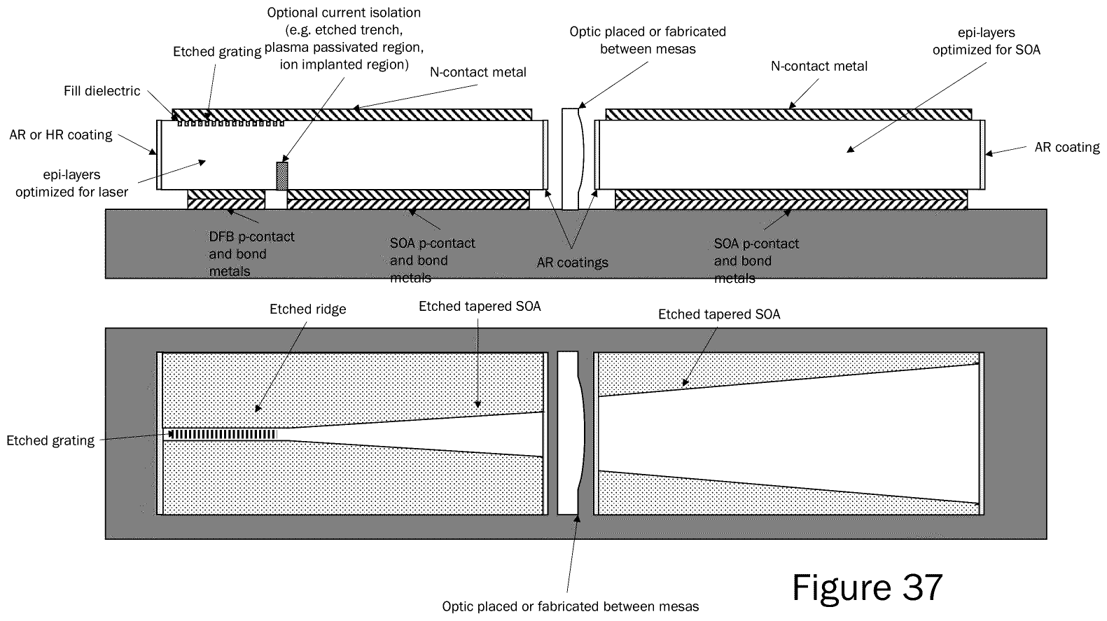

FIG. 37 includes simplified top-view and cross-sectional diagrams of a continuous mesa single-frequency MOPA or laser diode device with a separate mesa amplifier according to an example of the present invention. This example is similar to that of FIG. 34 with an optic arranged or formed between the mesas to improve coupling efficiency.

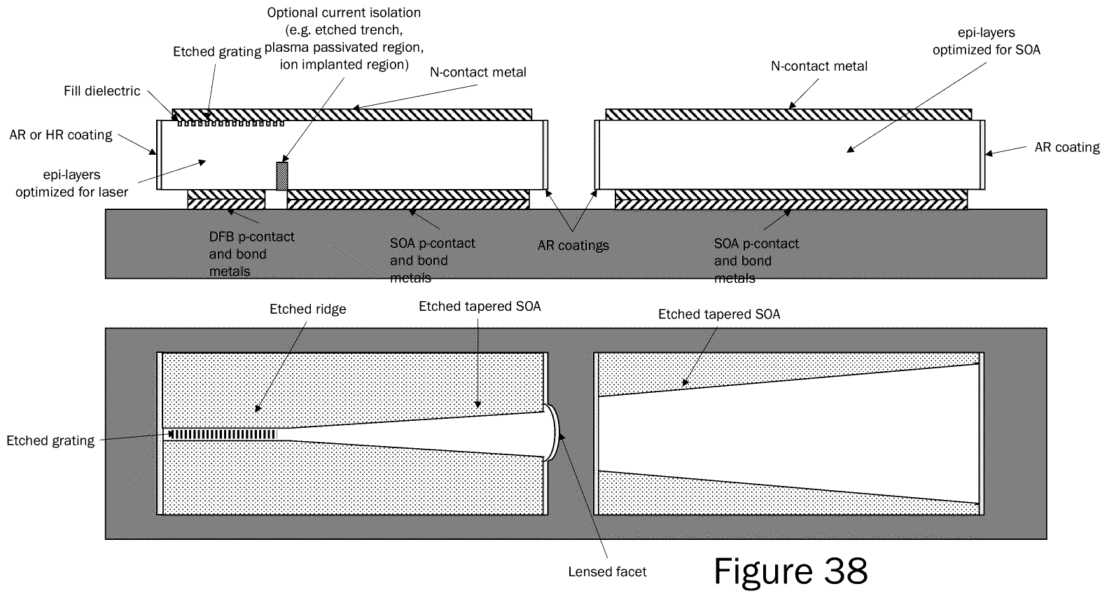

FIG. 38 includes simplified top-view and cross-sectional diagrams of a continuous mesa single-frequency MOPA or laser diode device with a separate mesa amplifier according to an example of the present invention. This example is similar to that of FIG. 34 with a lensed facet formed at an output of the amplifier section to improve coupling efficiency.

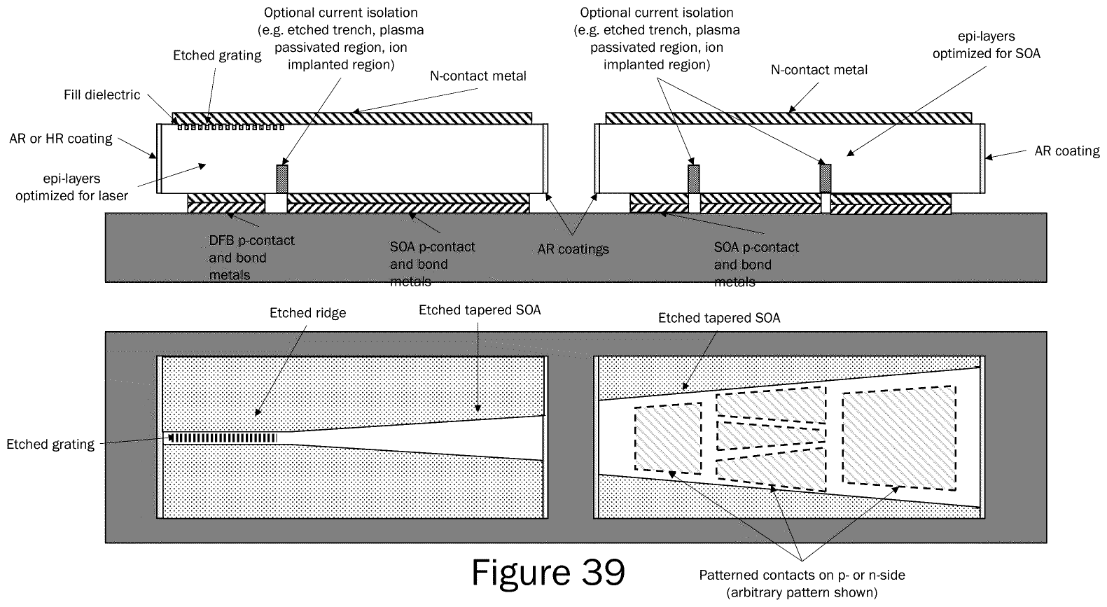

FIG. 39 includes simplified top-view and cross-sectional diagrams of a continuous mesa single-frequency MOPA or laser diode device with a separate mesa amplifier according to an example of the present invention. This example is similar to that of FIG. 34 with patterned contacts on the separate mesa amplifier. Also, one or more current isolation features may be included in the separate mesa amplifier.

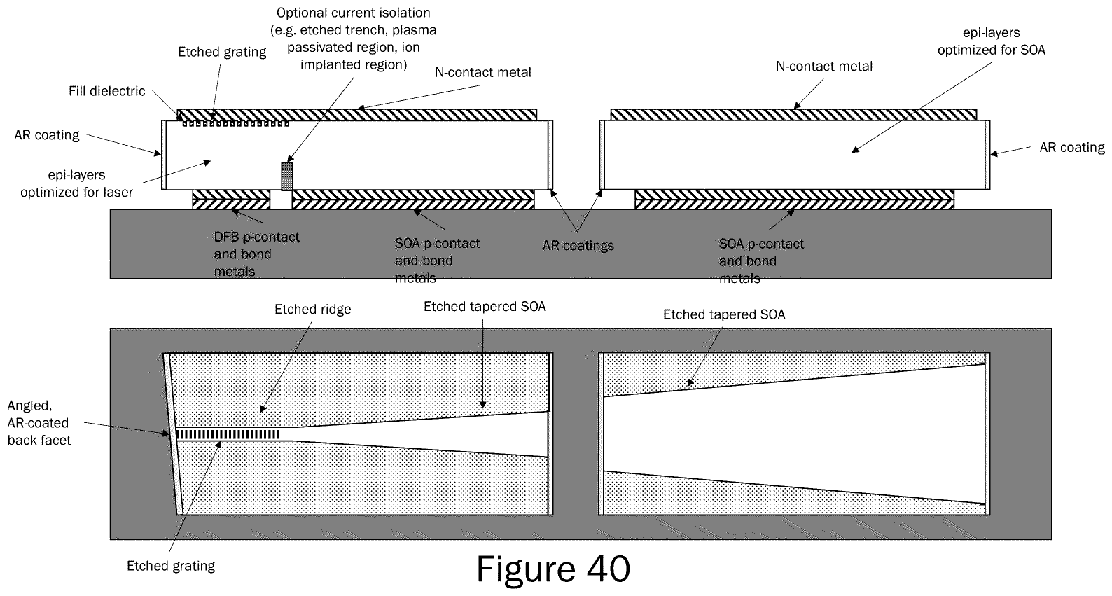

FIG. 40 includes simplified top-view and cross-sectional diagrams of a continuous mesa single-frequency MOPA or laser diode device with a separate mesa amplifier according to an example of the present invention. This example is similar to that of FIG. 34 with an angled back facet on the MOPA region or laser diode device.

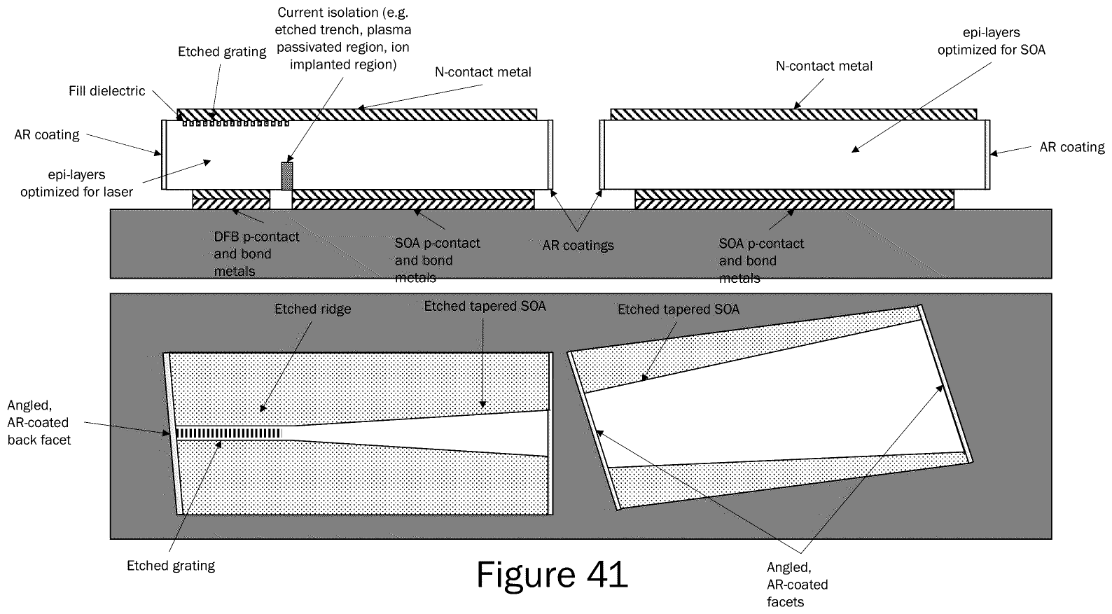

FIG. 41 includes simplified top-view and cross-sectional diagrams of a continuous mesa single-frequency MOPA or laser diode device with a separate mesa amplifier according to an example of the present invention. This example is similar to that of FIG. 40 with one or more angled facets on the separate mesa amplifier. The separate mesa amplifier may be formed at an angle to the MOPA region or laser diode device.

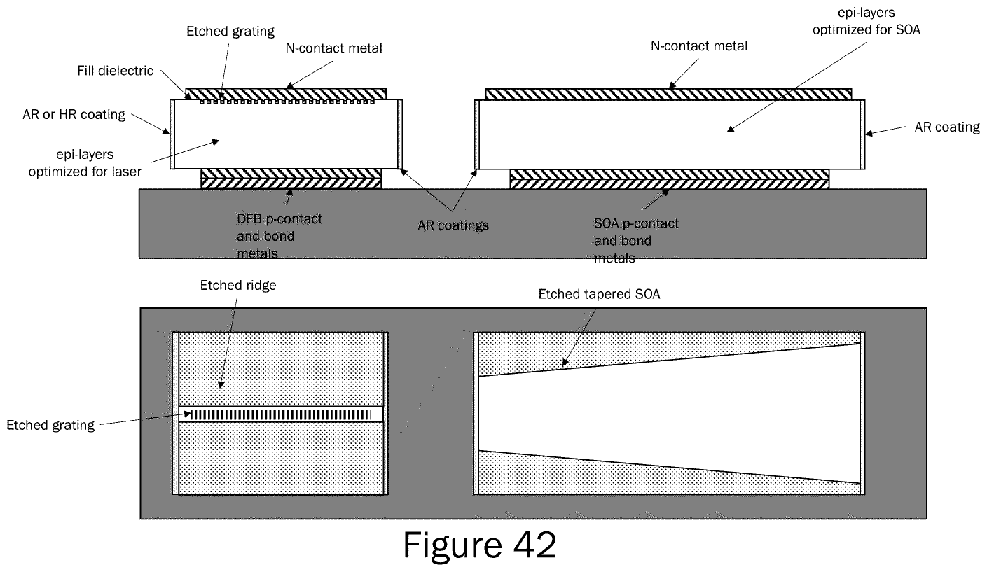

FIG. 42 includes simplified top-view and cross-sectional diagrams of a continuous mesa single-frequency MOPA or laser diode device with a separate mesa amplifier according to an example of the present invention. This example is similar to that of FIG. 34 without a tapered amplifier between the MOPA region or laser diode device and the separate mesa amplifier.

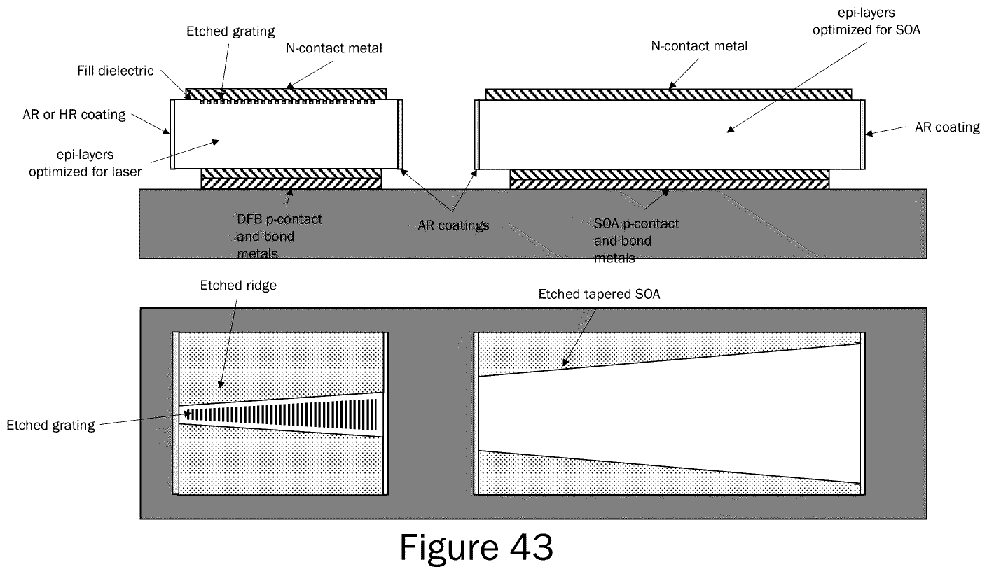

FIG. 43 includes simplified top-view and cross-sectional diagrams of a continuous mesa single-frequency MOPA or laser diode device with a separate mesa amplifier according to an example of the present invention. This example is similar to that of FIG. 43 with a tapered MOPA region or laser diode device.

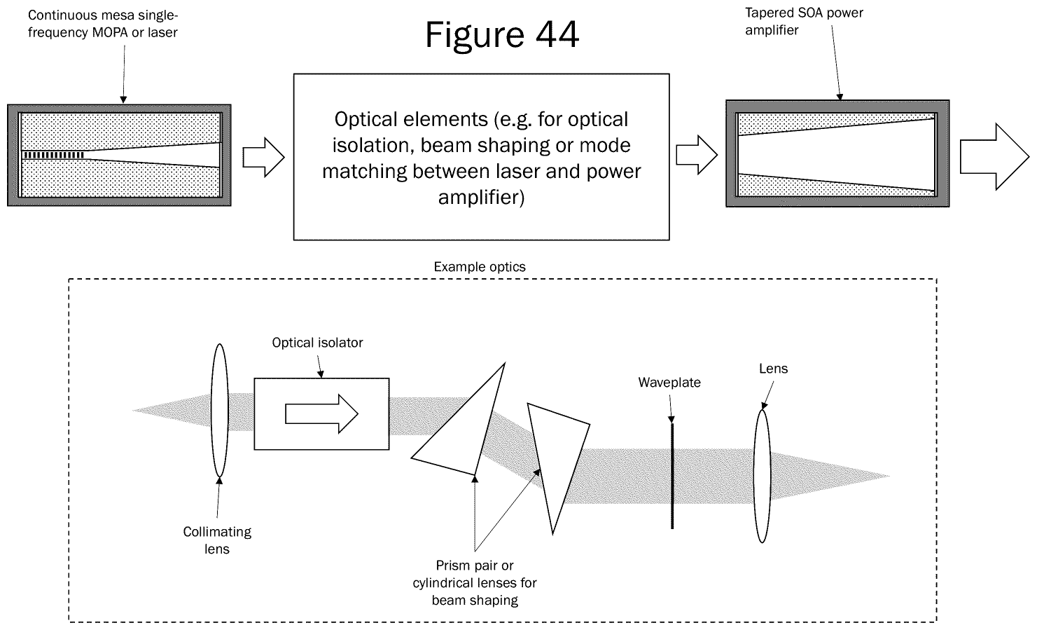

FIG. 44 includes simplified top-view and block diagrams of a continuous mesa single-frequency MOPA or laser diode device with a separate mesa amplifier according to an example of the present invention. This example is similar to that of FIG. 34 except the separate amplifier is a discrete device that is coupled to an output of the MOPA or laser diode device via optics. The MOPA or laser diode device and the separate amplifier may be arranged in a multi or single chip configuration. The optics may include one or more collimating lenses, isolators, wave plates, prisms, lenses, and the like. The optics may provide optical isolation, beam shaping, and/or mode matching between the laser and power amplifier.

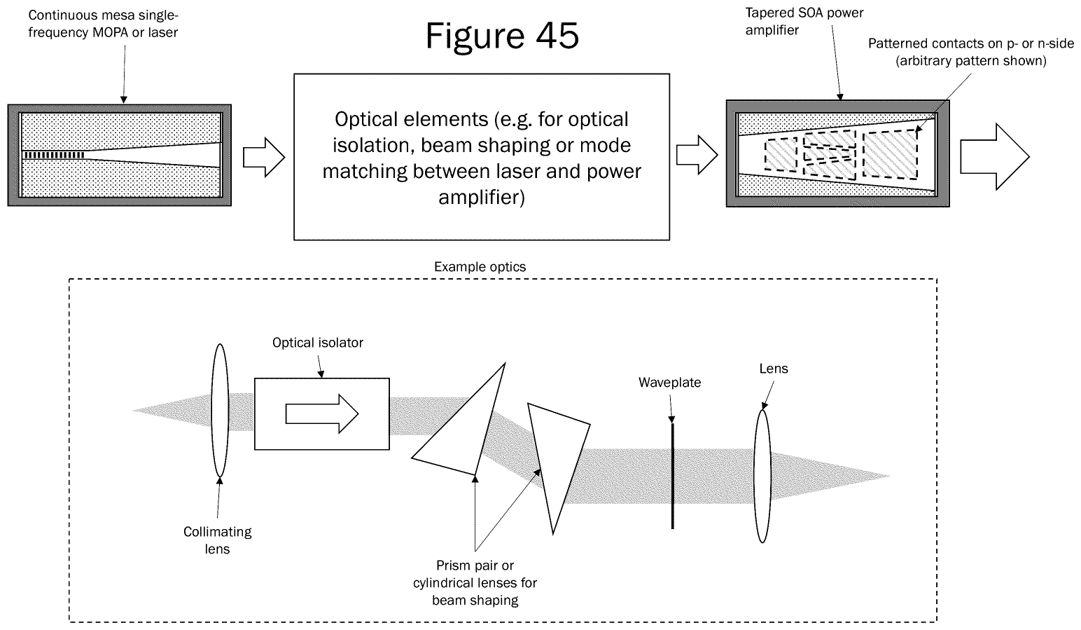

FIG. 45 includes simplified top-view and block diagrams of a continuous mesa single-frequency MOPA or laser diode device with a separate mesa amplifier according to an example of the present invention. This example is similar to that of FIG. 44 with patterned contacts on the separate mesa amplifier.

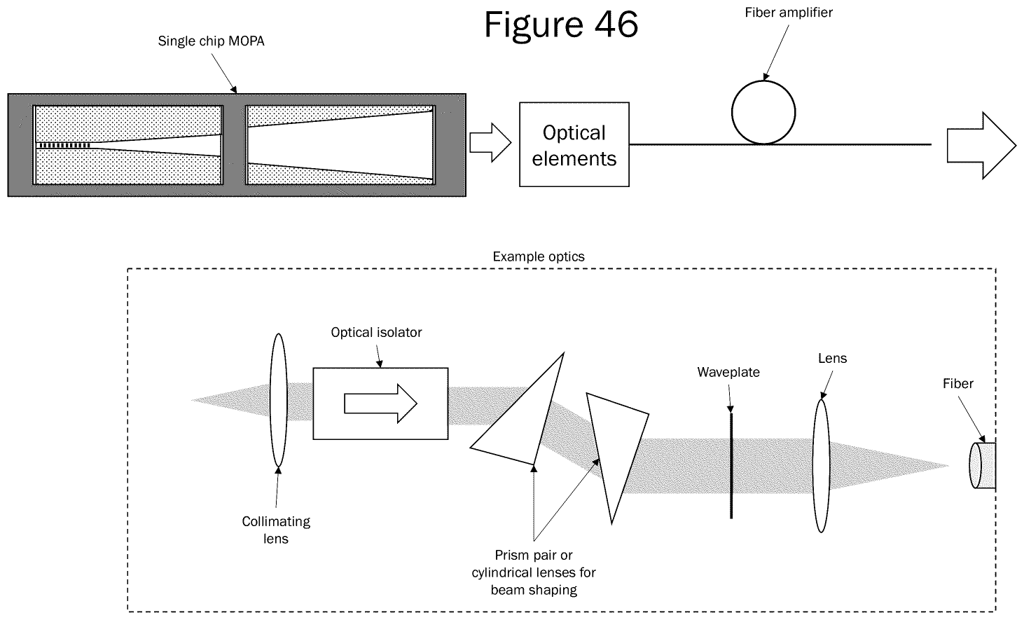

FIG. 46 includes simplified top-view and block diagrams of a continuous mesa single-frequency MOPA or laser diode device with a separate mesa amplifier according to an example of the present invention. This example is similar to that of FIG. 44 except the optics couple output from the separate mesa amplifier with a discrete fiber amplifier.

In an example, the present invention further provides an electro absorption modulator (EAM) device configured with one or more of the aforementioned examples. In an example, the electro absorption modulator device is configured within a portion of the cavity region from one of the above devices. The electro absorption modulator device is adapted to modulate the laser beam. Preferably, the electro absorption modulator device comprises a pair of electrodes coupled to the cavity region and configured to cause the laser beam to traverse, stop, or be modulated within the cavity region when biased appropriately in accordance with known techniques. Embodiments with these devices may be used in a number of different applications including airspeed sensors and communications.

In an example, the modulation techniques can vary depending upon the application. As an example, the modulation techniques for optical signals are configured to encode information onto light for transmission through optical fibers or free space. Examples of such modulation techniques include, among others, intensity modulation, phase modulation, frequency modulation, amplified shift keying, phase shift keying, frequency shift keying, and orthogonal frequency division multiplexing (“OFDM”), among others. In intensity modulation, information is encoded by varying the intensity of the optical signal. In an example, phase modulation involves encoding information by varying the phase of the optical signal. Changes in phase represent the data being transmitted. In an example, frequency modulation modulates the frequency of the optical carrier signal based on the input data. In an example, changes in frequency encode the information to be transmitted. In an example, amplitude shift keying modulates the amplitude of the optical carrier signal to represent digital data. The carrier signal is varied between two or more levels to convey binary or multilevel data. In an example, phase shift keying modulates the phase of the optical carrier signal to represent digital data. The phase of the carrier wave is shifted by specific angles to encode binary or multilevel data. In an example, frequency shift keying modulates the frequency of the optical carrier signal to represent digital data. In an example, the carrier frequency is shifted between predefined values to encode binary or multilevel data. In an example, OFDM is a modulation technique that divides the available spectrum into multiple orthogonal subcarriers. Each subcarrier is modulated using phase shift key or QAM (i.e., Quadrature Amplitude Modulation) to transmit data simultaneously in an example.

Further details of various EAM devices can be found throughout the present specification and more particularly below.

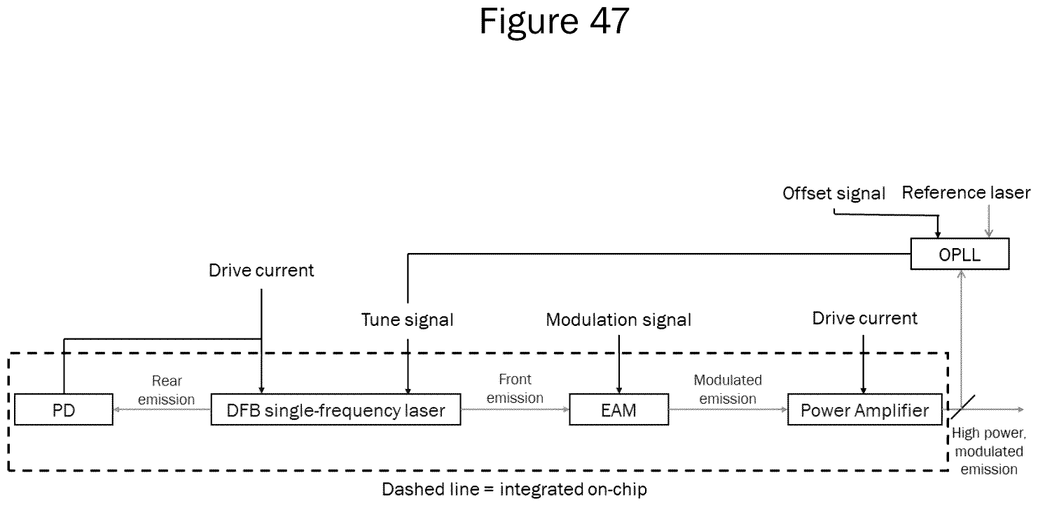

FIGS. 47-54 are simplified top-view, side-view, and cross-sectional view diagrams of various laser devices that include EAM device according to examples of the present invention. FIG. 47 includes an example driver architecture for the single-frequency MOPA device to achieve high quality mode, high power, single-frequency, modulated emission at a desired wavelength. The embodiment shown includes a rear power monitoring photodiode, tunable DFB laser, EAM and power amplifier integrated on-chip, however other configurations may be used. This example shows a feedback loop between the power monitoring photodiode and DFB laser drive current to maintain stable power and wavelength. Due to the dependence of wavelength on temperature, some embodiments may also include a means to control temperature of the DFB laser based on feedback from the photodiode. An EAM receives a modulation signal to modulate the single-frequency emission which is then amplified by the power amplifier. Finally, the high power, single-frequency, modulated output is split to an optical phase-locked loop to produce a tuning signal and lock the laser to a desired wavelength. The tuning signal may be used for tuning a frequency of the DFB laser.

In some embodiments, the DFB laser is driven to provide stable single-frequency emission and power. A rear emission from the DFB laser may be received by an on or off chip photodiode. Signals from the photodiode are used as feedback to drive current to the DFB laser to maintain stable power and wavelength. A front emission from the DFB laser goes through the EAM and power amplifier. The modulated and amplified emission is split (e.g., a 99%/1% splitter) so that most of the power is provided as usable output. A portion of the emission is directed to the optical phase-locked loop (OPLL). The OPLL may have a reference laser and offset signal as inputs and provide an output tuning signal that is used to tune the DFB laser.

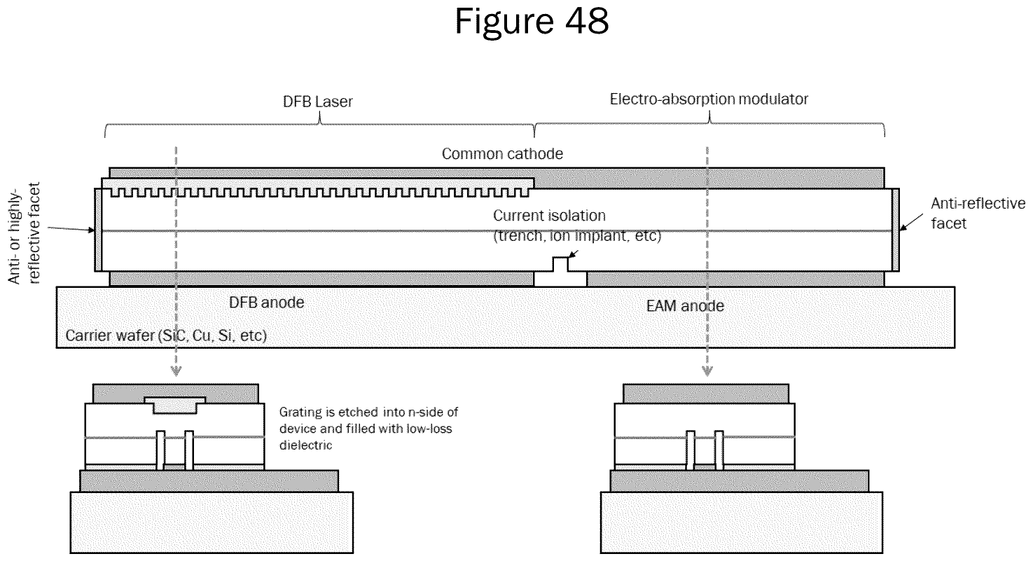

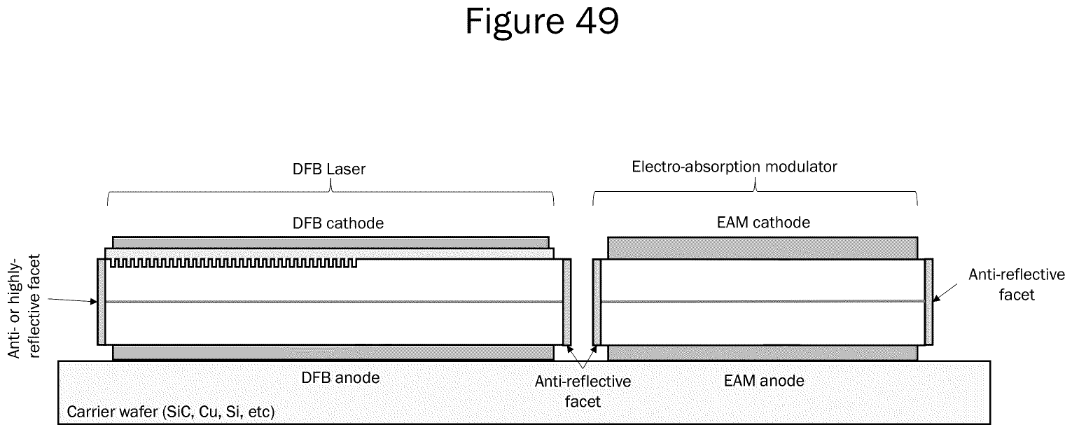

FIG. 48 includes simplified axial and lateral cross-sectional diagrams of a continuous mesa single-frequency laser diode device with an EAM according to an example of the present invention. The continuous mesa device may be formed on a carrier substrate using the transfer processes described herein. The device includes an etched grating region and a modulator region. The etched grating region may be formed over the laser diode in an n-side of the device. The modulator region in this example may be formed from the same materials as the laser diode and include the same well and ridge waveguide structures. In some embodiments, the ridge waveguide may be formed using trenches as shown in the lateral cross-sectional diagrams. In this example the ridge waveguide is formed on the p-side, although the ridge waveguide may be formed on the n-side after transfer in some embodiments. Current isolation between the laser diode and the modulator may be provided (e.g., trench or ion implant). The optical feedback may be provided in the laser diode portion, and output from the laser diode may be provided to the modulator. The electrical contacts include a common cathode and segmented anode, however common anode and segmented cathode or segmented anode and cathode may be used. The cathode and/or anode may be a patterned contact or an un-patterned contact in accordance with embodiments described herein. The EAM contact may be used to bias the wells in the modulator portion to make the modulator optically absorbing, optically transparent, or optically amplifying to the laser output. In an example, the modulator is pumped between transparency and absorbance according to a modulation signal. The device can provide a high quality mode, single-frequency, fast-modulated emission at a desired wavelength. Alternate embodiments may include a co-packaged laser diode device and a modulator device where one or both of the devices may be separately formed using the transfer processes described herein. Other alternate embodiments may include a laser diode device and modulator device where both devices are separately formed and fabricated on the same substrate using the transfer processes described herein. These devices may use the same or different epitaxial structures. An example is shown in FIG. 49.

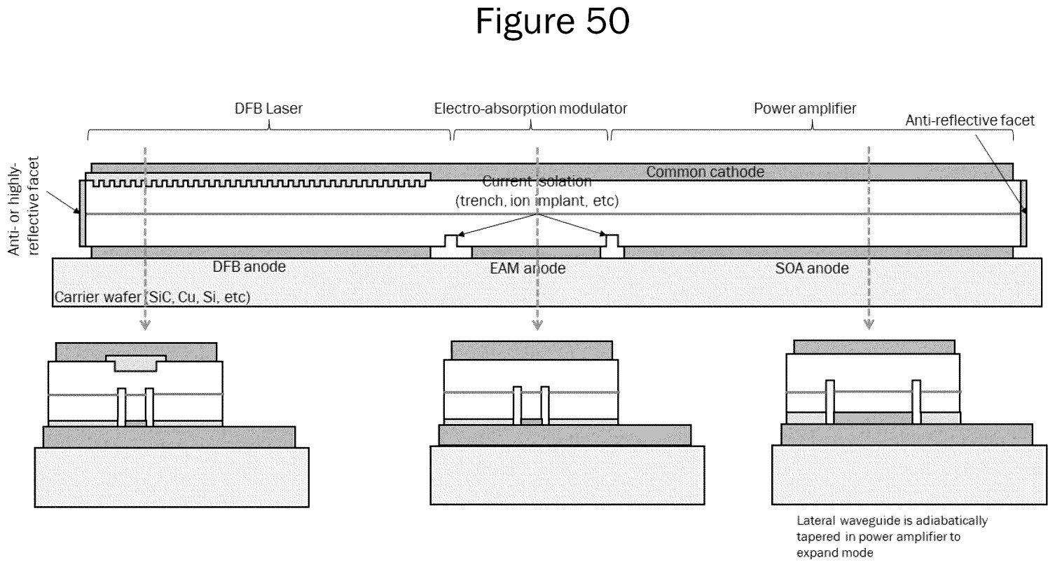

FIG. 50 includes simplified axial and lateral cross-sectional diagrams of a continuous mesa single frequency modulated device according to an example of the present invention. The continuous mesa device may be formed on a carrier substrate using the transfer processes described herein. The device includes an etched grating region, a modulator region, and an amplifier region. The etched grating region may be formed over the laser diode in a n-side of the device. The modulator and amplifier regions in this example may be formed from the same materials as the laser diode and include the same well and ridge waveguide structures. In an embodiment, the ridge waveguide may be tapered in at least the amplifier region. This can expand lasing mode and reduce power density while maintaining beam quality and spatial mode characteristics. The device includes a common cathode and segmented anode, however common anode and segmented cathode or segmented anode and cathode may be used. The cathode and/or anode may be a patterned contact or an un-patterned contact in accordance with embodiments described herein. Output from the laser diode may be modulated using the EAM as described previously, and the modulated emission may be amplified using the amplifier. One or more current isolation features, such as etched trenches or ion implanted regions, may be included between the sections. Alternate embodiments may include a co-packaged laser diode device, modulator device, and/or amplifier device where one or more of the devices may be separately formed using the transfer processes described herein. Other alternate embodiments may include a laser diode device and modulator device where one or more of the devices are separately formed and fabricated on the same substrate using the transfer processes described herein. These devices may use the same or different epitaxial crystal structures.

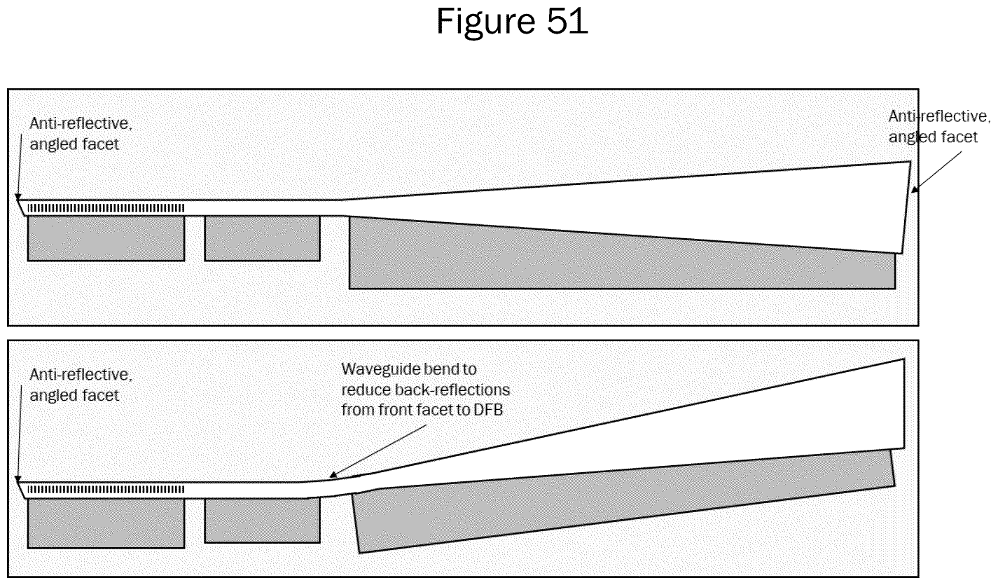

FIG. 51 includes simplified top-view diagrams of continuous mesa single-frequency modulated MOPA devices with segmented contacts according to examples of the present invention. The segmented contacts may be patterned or un-patterned in accordance with embodiments described herein. The continuous mesa devices may be formed on a carrier substrate using the transfer processes described herein. These examples both include an etched grating region, a modulator region, and an amplifier region. The etched grating region may be formed over the laser diode in a n-side of the device. The modulator and amplifier regions in this example may be formed from the same materials as the laser diode and include the same well and ridge waveguide structures. In an embodiment, the ridge waveguide may be tapered in at least the amplifier region. Output from the laser diode may be modulated using the EAM as described previously, and the modulated emission may be amplified using the amplifier. One or more current isolation features, such as etched trenches or ion implanted regions, may be included between the sections. These examples show two methods to reduce reflections from the front facets of the device by angling the facet and/or curving the lateral waveguide. The angled facet and/or curved lateral waveguide can reduce or eliminate lasing in the amplifier portion of the device to preserve single frequency and/or single mode emissions. The angled facet and/or curved lateral waveguide can reduce or eliminate reflection from the front facet back into the modulator and laser diode portions of the device. Both examples show an angled back facet. Not all embodiments include an angled facet. Some embodiments may include a co-package scheme with an optical isolator to reduce or eliminate amplified spontaneous emission from the amplifier. The optical isolator may use polarization to allow light to propagate in only one direction. Alternate embodiments may include a co-packaged laser diode device, modulator device, and/or amplifier device where one or more of the devices may be separately formed using the transfer process described herein.

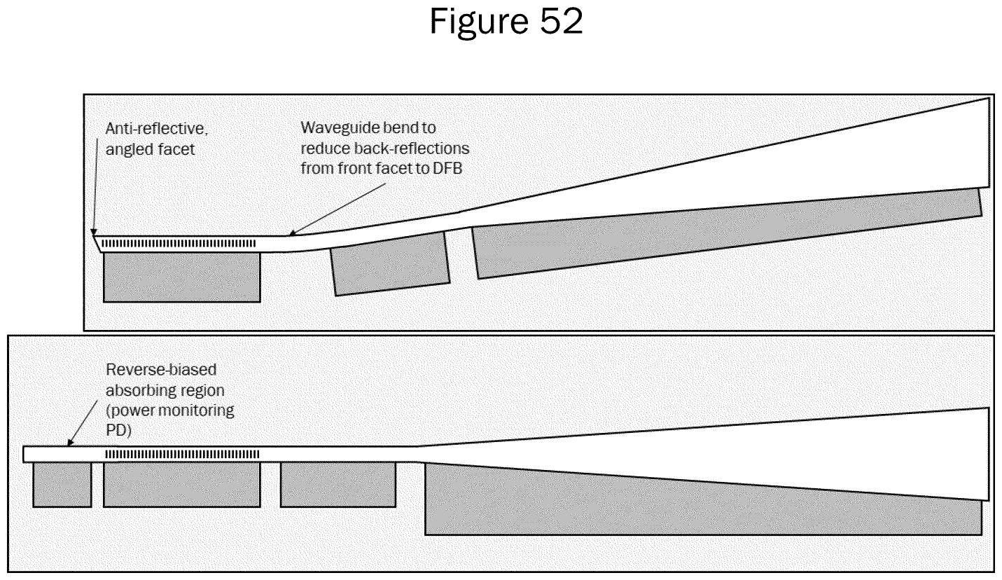

FIG. 52 includes simplified top-view diagrams of continuous mesa single-frequency modulated MOPA devices with segmented contacts according to the examples of the present invention. The segmented contacts may be patterned or un-patterned in accordance with embodiments described herein. The continuous mesa devices may be formed on a carrier substrate using the transfer processes described herein. Both devices may include a laser diode region, a modulator region, and an amplifier region as described previously. The top diagram shows a device with a curved waveguide similar to that of FIG. 51 only with the curve occurring before the modulator portion. The bottom diagram shows the addition of a power monitoring photodiode that can be used to determine the output power from the grating laser section. Embodiments described herein may include one or both of the curved waveguide and power monitoring photodiode features shown in these examples.

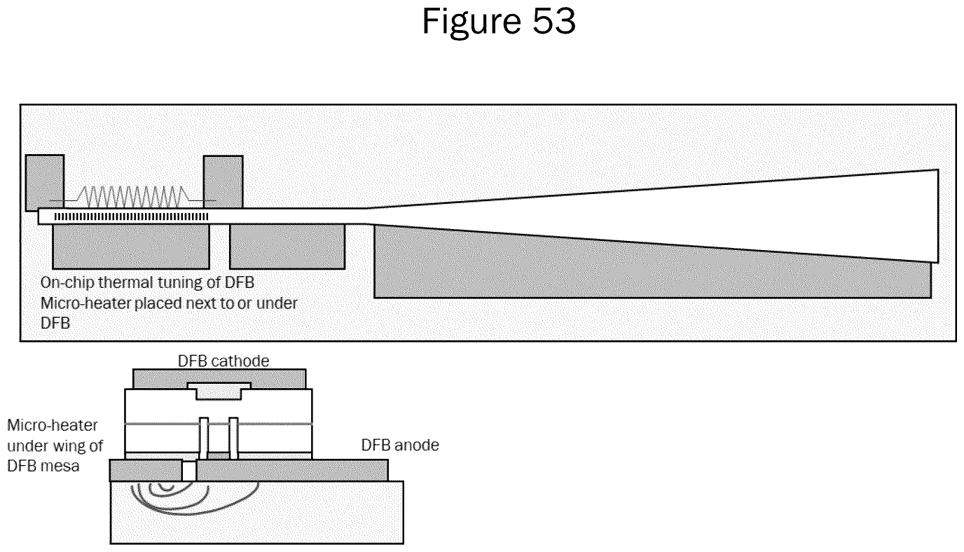

FIG. 53 includes simplified top-view and cross-sectional diagrams of a continuous mesa single-frequency modulated MOPA device with segmented contacts according to the examples of the present invention. The segmented contacts may be patterned or un-patterned in accordance with embodiments described herein. The continuous mesa devices may be formed on a carrier substrate using the transfer processes described herein. The device depicted is similar to that of FIG. 50 with the addition of a micro-heater embedded on a side or underneath the wing of the grating section. This micro-heater can be used to thermally tune the wavelength of the device emission. The micro-heater may heat the laser diode based on a signal from a power monitoring photodiode and/or optical phase-locked loop and control electronics to provide a stable frequency and/or wavelength. Embodiments described herein may include heating features as shown in this example.

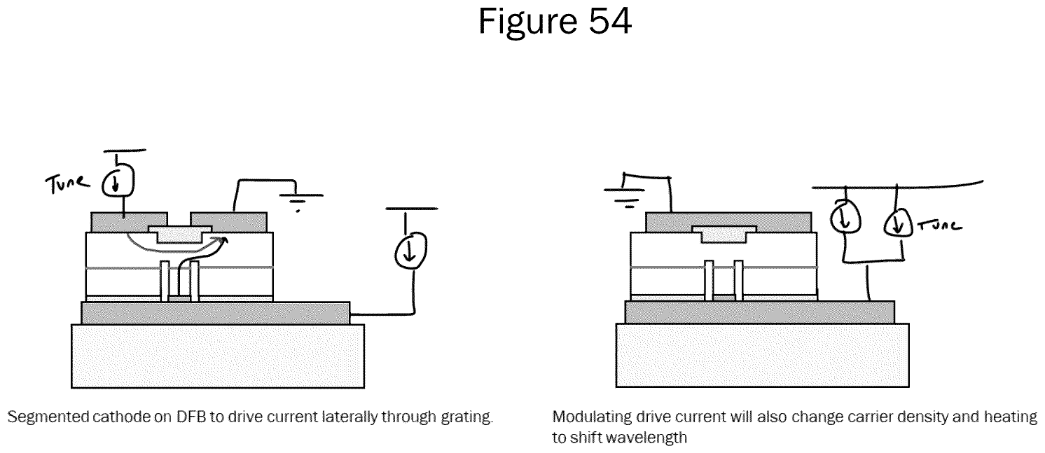

FIG. 54 includes simplified cross-sectional diagrams of other possible wavelength tuning methods for a single-frequency device according to the examples of the present invention. The subfigures depict cross-sections in the grating sections of the device. The devices may be formed on a carrier substrate using the transfer processes described herein. The left subfigure shows an example of a tuning method using a segmented cathode used to laterally drive current across the device. The structure allows the segmented cathode to drive the current laterally through the grating. The segmented cathode may be a patterned contact or un-patterned contact in accordance with embodiments described herein. The right subfigure shows an example of a tuning method using modulation of the drive current to the device. Embodiments described herein may include tuning features shown in these examples.

In an example, the device further comprises a heating device operably coupled to the first region of the cavity region. In an example, the device has a drive circuit coupled to the pair of electrodes. In an example, the device has a common first electrode overlying the cavity region and a second electrode configured with one or more isolation regions to form the master oscillator device and first power amplifier. In an example, the device has a common first electrode overlying the cavity region and a second electrode configured with one or more isolation regions to form the master oscillator device, the first power amplifier, and the electro adsorption modulator device.

As used herein, the term GaN substrate is associated with Group III-nitride based materials including GaN, InGaN, AlGaN, or other Group III containing alloys or compositions that are used as starting materials. Such starting materials include polar GaN substrates (i.e., substrate where the largest area surface is nominally an (h k 1) plane wherein h=k=0, and 1 is non-zero).

As used herein, the term substrate is associated with both GaN substrates as well as substrates on which can be grown epitaxially GaN, InGaN, AlGaN, or other Group III containing alloys or compositions that are used as starting materials. Such substrates include SiC, sapphire, silicon, and germanium, among others. Substrate may also refer to substrates on which can be grown epitaxially GaAs, AlAs, InAs, GaP, AlP, InP, or other like Group III containing alloys or compositions that are used as starting materials. Such substrates include GaAs, GaP, Ge and Si, among others.

As used herein, the terms carrier or carrier wafer refer to wafer to which epitaxial device material is transferred. The carrier may be composed of a single material and be either single crystalline or polycrystalline. The carrier may also be a composite of multiple materials. For example, the carrier could be a silicon wafer of standard dimensions, or it could be composed of polycrystalline AlN.

As shown, the present device can be enclosed in a suitable package. Such package can include those such as in TO-38 and TO-56 headers. Other suitable package designs and methods can also exist, such as TO-9 or flat packs where fiber optic coupling is required and even non-standard packaging. In a specific embodiment, the present device can be implemented in a co-packaging configuration.

While the above is a full description of the specific embodiments, various modifications, alternative constructions and equivalents may be used. As an example, the packaged device can include any combination of elements described above, as well as outside of the present specification. As used herein, the term “substrate” can mean the bulk substrate or can include overlying growth structures such as a gallium and nitrogen containing epitaxial region, or functional regions such as n-type GaN, combinations, and the like. Additionally, the examples illustrate waveguide structures in normal configurations, there can be variations, e.g., other angles and polarizations. As mentioned, the various beam combining techniques are desirably configured to increase beam intensity efficiently without any detrimental interference between any pair of beams.

### REFERENCES

### D. Paboeuf, G. Lucas-Leclin, P. Georges, N. Michel, M. Krakowski, J. Lim, S. Sujecki, and E. Larkins,

“Narrow-line coherently combined tapered laser diodes in a Talbot external cavity with a volume Bragg grating,” Appl. Phys. Lett. 93(21), 211102 (2008).
R. K. Huang, B. Chann, L. J. Missagia, S. J. Augst, M. K. Connors, G. W. Turner, A. Sanchez-Rubio, J. P. Donnelly, J. L. Hostetler, C. Miester, and F. Dorsch, “Coherent combination of slab-coupled optical waveguide lasers,” Proc. SPIE 7230, 72301G (2009).

### S. M. Redmond, D. J. Ripin, C. X. Yu, S. J. Augst, T. Y. Fan, P. A. Thielen, J. E. Rothenberg, and G. D.

Goodno, “Diffractive coherent combining of a 2.5 kW fiber laser array into a 1.9 kW Gaussian beam,” Opt. Lett. 37(14), 2832-2834 (2012).

What is claimed is:

1. A laser device including a gallium and nitrogen containing material, the device comprising:
a carrier substate member comprising a front side and a back side;
a bonding material overlying the front side of the carrier substrate member and configured to bond an overlying transferred material to the front side of the carrier substrate member;
at least one p-type contact region overlying the bonding material and configured to form a thermal path and an electrical path to and from the bonding material;
a p-type gallium and nitrogen containing region overlying the at least one p-type contact region;
an active region overlying the p-type gallium and nitrogen containing region, the active region comprising a plurality of quantum well regions;
an n-type gallium and nitrogen containing region overlying the active region, the n-type gallium and nitrogen containing region comprising a plurality of sub-regions;
at least one n-type contact region overlying the n-type gallium and nitrogen containing region; and
a waveguide region including a laser diode portion configured to propagate electromagnetic radiation and output a laser beam; and
an electro absorption modulator (EAM) portion configured to modulate the laser beam, the EAM portion associated with a pair of electrodes configured to cause the laser beam to traverse, stop, or be modulated within the EAM portion.

2. The device of claim 1 wherein at least a portion of the at least one n-type contact region comprises a spatial pattern having a dimension and geometry to achieve a predetermined mode quality.

3. The device of claim 1 wherein the laser diode portion of the waveguide region is associated with an etched grating disposed in the n-type gallium and nitrogen containing region.

4. The device of claim 1 wherein the laser diode portion and the EAM portion are separated by a current isolation region.

5. The device of claim 1 wherein the at least one p-type contact region includes an anode associated with the laser diode region and a separate anode associated with the EAM region.

6. The device of claim 1 wherein the pair of electrodes associated with the EAM portion include an n-type contact region and a p-type contact region.

7. A laser device including a gallium and nitrogen containing material, the device comprising:
a carrier substate member comprising a front side and a back side;
a bonding material overlying the front side of the carrier substrate member and configured to bond an overlying transferred material to the front side of the carrier substrate member;
a p-type contact region overlying the bonding material and configured to form a thermal path and an electrical path to and from the bonding material;
a p-type gallium and nitrogen containing region overlying the p-type contact region;
an active region overlying the p-type gallium and nitrogen containing region, the active region comprising a plurality of quantum well regions;
an n-type gallium and nitrogen containing region overlying the active region, the n-type gallium and nitrogen containing region comprising a plurality of sub-regions;
an n-type contact region overlying the n-type gallium and nitrogen containing region;
a cavity region formed between a first facet and a second facet and configured to propagate electromagnetic radiation through the cavity region and output a laser beam from one of the first facet or the second facet; and
an electro absorption modulator (EAM) device arranged to receiver the laser beam from the cavity region and adapted to modulate the laser beam, the electro absorption modulator device comprising a pair of electrodes configured to cause the laser beam to traverse, stop, or be modulated within the cavity region.

8. The device of claim 7 wherein the n-type contact region comprises a spatial pattern having a dimension and a geometry to achieve a predetermined mode quality.

9. The device of claim 7 wherein the cavity region is separated from the EAM device by a gap.

10. The device of claim 7 wherein the cavity region includes an etched grating overlying the n-type gallium and nitrogen containing region.

11. A laser device including a gallium and nitrogen containing material, the device comprising:
a carrier substate member comprising a front side and a back side;
a bonding material overlying the front side of the carrier substrate member and configured to bond an overlying transferred material to the front side of the carrier substrate member;
at least one p-type contact region overlying the bonding material and configured to form a thermal path and an electrical path to and from the bonding material;
a p-type gallium and nitrogen containing region overlying the at least one p-type contact region;
an active region overlying the p-type gallium and nitrogen containing region, the active region comprising a plurality of quantum well regions;
an n-type gallium and nitrogen containing region overlying the active region, the n-type gallium and nitrogen containing region comprising a plurality of sub-regions;
at least one n-type contact region overlying the n-type gallium and nitrogen containing region; and
a cavity region formed between a first facet and a second facet and configured to propagate electromagnetic radiation through the cavity region and output a laser beam from one of the first facet or the second facet, the cavity region including a laser diode portion, an electro absorption modulator (EAM) portion, and an amplifier portion;
wherein the EAM portion is configured to modulate the laser beam, the EAM portion associated with a pair of electrodes configured to cause the laser beam to traverse, stop, or be modulated within the EAM portion, and
wherein the amplifier portion is configured to expand lasing mode and reduce power density of the laser beam.

12. The device of claim 11 wherein at least a portion of the at least one n-type contact region comprises a spatial pattern having a dimension and a geometry to achieve a predetermined mode quality.

13. The device of claim 11 wherein the laser diode portion of the cavity region is associated with an etched grating disposed in the n-type gallium and nitrogen containing region.

14. The device of claim 11 wherein the laser diode portion and the EAM portion are separated by a current isolation region, and the EAM portion and the amplifier portion are separated by a current isolation portion.

15. The device of claim 11 wherein the EAM portion is disposed between the laser diode portion and the amplifier portion.

16. The device of claim 11 wherein the cavity is tapered in at least the amplifier portion.

17. The device of claim 11 wherein the cavity includes a curve or bend between the laser diode portion and the amplifier portion.

18. The device of claim 11 wherein at least one of the first facet or the second facet is angled relative to a longitudinal axis of the cavity.

19. The device of claim 11 further comprising a power monitoring photodiode configured to determine output power from the laser diode portion.

20. The device of claim 11 further comprising at least one of a micro-heater configured to thermally tune a wavelength of the laser beam, a segmented cathode on the laser diode portion configured to laterally drive current to tune a wavelength of the laser beam, or a means for modulating a drive current to tune a wavelength of the laser beam.
